(19) United States
(12) Patent Application Publication
(10) Pub. No.: US 2025/0044697 A1
(43) Pub. Date: Feb. 6, 2025

(54) COMPOSITION FOR FORMING SILICON-CONTAINING RESIST UNDERLAYER FILM HAVING CARBONYL STRUCTURE

(71) Applicant: NISSAN CHEMICAL CORPORATION, Tokyo (JP)

(72) Inventors: Wataru Shibayama, Toyama-shi (JP); Satoshi Takeda, Toyama-shi (JP); Makoto Nakajima, Toyama-shi (JP)

(73) Assignee: NISSAN CHEMICAL CORPORATION, Tokyo (JP)

(21) Appl. No.: 18/910,475

(22) Filed: Oct. 9, 2024

Related U.S. Application Data
(63) Continuation of application No. 16/499,533, filed on Sep. 30, 2019.

(30) Foreign Application Priority Data
Mar. 31, 2017 (JP) 2017-072076

(51) Int. Cl. G03F 7/11; C08G 77/00; C08G 77/14; C09D 183/06; H01L 21/02; H01L 21/027; H01L 21/266; H01L 21/308

(52) U.S. Cl. CPC G03F 7/11; C08G 77/14; C09D 183/06; H01L 21/02057; H01L 21/0274; H01L 21/266; H01L 21/308; C08G 77/80

(57) ABSTRACT

A method for producing a semiconductor device includes applying a composition for forming a silicon-containing resist underlayer film, wherein the composition comprises a polysiloxane having a unit structure including a carbonyl group-containing functional group, wherein the silicon-containing resist underlayer film is used as a mask layer in a step of removing the mask layer with hydrogen peroxide-containing chemical after transfer of a pattern to an underlayer by lithography process onto a semiconductor substrate, followed by baking the composition, to thereby form a resist underlayer film, applying a resist composition onto resist underlayer film to thereby form a resist film, exposing the resist film to light, developing the resist after the light exposure to thereby form a resist pattern, etching the resist underlayer film with the resist pattern, processing the semiconductor substrate with the patterned resist and resist underlayer film, and removing the mask layer with a hydrogen peroxide-containing chemical.

The present application is a continuation application of U.S. application Ser. No. 16/499,533 filed Sep. 30, 2019, which is a U.S. national stage application of PCT/JP2018/013879 filed Mar. 30, 2018, claiming priority to Japanese Application No. 2017-072076 filed Mar. 31, 2017. Each of the prior applications is incorporated herein by reference in its entirety.

### TECHNICAL FIELD

The present invention relates to a composition for forming an underlayer film between a substrate and a resist (e.g., a photoresist or an electron beam resist) for use in the production of a semiconductor device. More particularly, the present invention relates to a resist underlayer film-forming composition for lithography for forming an underlayer film used as a layer under a photoresist in a lithography process for the production of a semiconductor device. Also, the present invention relates to a method for forming a resist pattern using the underlayer film-forming composition.

### BACKGROUND ART

Fine processing by lithography using photoresists has been conventionally performed in the production of semiconductor devices. The fine processing is a processing method involving formation of a photoresist thin film on a semiconductor substrate (e.g., a silicon wafer); irradiation of the thin film with active rays (e.g., ultraviolet rays) through a mask pattern having a semiconductor device pattern drawn thereon; development of the irradiated thin film; and etching of the substrate with the resultant photoresist pattern serving as a protective film, to thereby form, on the surface of the substrate, fine irregularities corresponding to the pattern. In recent years, active rays having a shorter wavelength have tended to be used (i.e., shifting from KrF excimer laser (248 nm) to ArF excimer laser (193 nm)) in association with an increase in the degree of integration of semiconductor devices. This tendency causes a serious problem in terms of the influence of reflection of active rays from a semiconductor substrate.

A film known as a hard mask and containing a metal element (e.g., silicon or titanium) has been used as an underlayer film between a semiconductor substrate and a photoresist. In this case, the components of the photoresist significantly differ from those of the hard mask, and thus the rate of removal of these by dry etching greatly depends on the types of gas used for dry etching. The appropriate selection of a gas type enables the hard mask to be removed by dry etching without a large reduction in the thickness of the photoresist. Thus, in the recent production of semiconductor devices, a resist underlayer film has been disposed between a semiconductor substrate and a photoresist so as to achieve various effects, such as an antireflection effect. Although compositions for resist underlayer films have hitherto been studied, demand has arisen for development of a novel material for resist underlayer films because of, for example, various properties required for the films.

For example, resist underlayer films have been proposed which contain a polysiloxane produced from a silane having an ester bond (see Patent Documents 1, 2, and 3).

### PRIOR ART DOCUMENTS

### Patent Documents

Patent Document 1: Japanese Patent Application Publication No. 2007-226170 (JP 2007-226170 A)

Patent Document 2: Japanese Patent Application Publication No. 2004-310019 (JP 2004-310019 A)

Patent Document 3: International Publication Pamphlet WO 2006/057782

### SUMMARY OF THE INVENTION

### Problems to be Solved by the Invention

A multilayer process has been widely used in association with micronization of implant layers for state-of-the-art semiconductor devices. In general, the multilayer process involves dry etching for pattern transfer to an underlayer, and also involves dry etching for final processing of a substrate. Also, dry etching or an ashing process may be used for removal of mask residues after the substrate processing; for example, removal of organic underlayer films, including resists and resist underlayer films. However, such a process causes damage to the substrate, and thus an improvement in the process is demanded.

An object of the present invention is to provide a resist underlayer film-forming composition for lithography that can be used in the production of a semiconductor device. Specifically, an object of the present invention is to provide a resist underlayer film-forming composition for lithography for forming a resist underlayer film that can be used as a hard mask. Another object of the present invention is to provide a resist underlayer film-forming composition for lithography for forming a resist underlayer film that can be used as an anti-reflective coating. Still another object of the present invention is to provide a resist underlayer film for lithography that does not intermix with a resist and is dry-etched at a higher rate as compared with the resist, and to provide a resist underlayer film-forming composition for forming the underlayer film.

### Means for Solving the Problems

A first aspect of the present invention is a composition for forming a silicon-containing resist underlayer film, the composition being characterized by comprising a polysiloxane having a unit structure including a carbonyl group-containing functional group, wherein the silicon-containing resist underlayer film is used as a mask layer in a step of removing the mask layer with a hydrogen peroxide-containing chemical after transfer of a pattern to an underlayer by a lithography process.

A second aspect of the present invention is the composition for forming a silicon-containing resist underlayer film according to the first aspect, wherein the unit structure including a carbonyl group-containing functional group includes a cyclic acid anhydride group, a cyclic diester group, or a diester group.

A third aspect of the present invention is the composition for forming a silicon-containing resist underlayer film according to the first aspect, wherein the polysiloxane is a hydrolysis condensate of a hydrolyzable silane containing a silane of the following Formula (1):

R¹ₐR²_{b}Si(R³)_{4-(a+b)} Formula (1)

[wherein R¹ is an organic group of the following Formula (1-1), (1-2), (1-3), (1-4), (1-5), or (1-6):

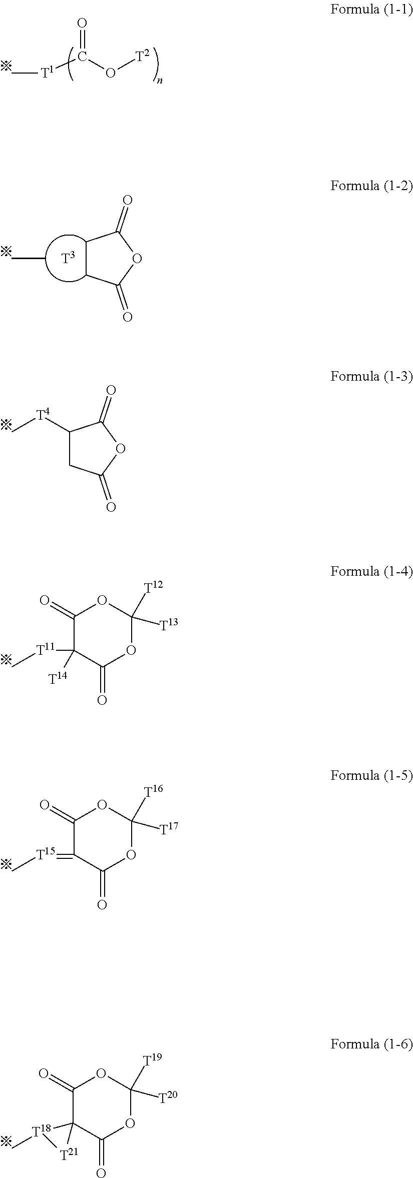

(wherein T¹ and T⁴ are each an alkylene group or a cyclic alkylene group; T² is an alkyl group; T³ is a cyclic alkylene group; n is an integer of 1 or 2; T¹¹, T¹⁵, and T¹⁸ are each an alkylene group, a cyclic alkylene group, an alkenylene group, an arylene group, a sulfur atom, an oxygen atom, an oxycarbonyl group, an amide group, a secondary amino group, or any combination of these; T¹², T¹³, T¹⁴, T¹⁶, T¹⁷, T¹⁹, and T²⁰ are each a hydrogen atom or an alkyl group; T²¹ is an alkylene group; and * is a site of bonding to the silicon atom directly or via a linking group) and is bonded to the silicon atom via an Si—C bond;
R² is an alkyl group, an aryl group, a halogenated alkyl group, a halogenated aryl group, an alkenyl group, or an organic group having an epoxy group, an acryloyl group, a methacryloyl group, a mercapto group, an amino group, or a cyano group, and is bonded to the silicon atom via an Si—C bond;
R³ is an alkoxy group, an acyloxy group, or a halogen atom; and
a is an integer of 1, b is an integer of 0 or 1, and a +b is an integer of 1 or 2].

A fourth aspect of the present invention is the composition for forming a silicon-containing resist underlayer film according to the first or second aspect, wherein the polysiloxane further has a unit structure including an amide group-containing organic group.

A fifth aspect of the present invention is the composition for forming a silicon-containing resist underlayer film according to the fourth aspect, wherein the amide group is a sulfonamide group or a diallyl isocyanurate group.

A sixth aspect of the present invention is the composition for forming a silicon-containing resist underlayer film according to the first aspect, wherein the polysiloxane is a cohydrolysis condensate of a hydrolyzable silane containing a silane of Formula (1) and a silane of the following Formula (2):

R⁴ₐR⁵_{b}Si(R⁶)_{4-(a+b)} Formula (2)

[wherein R⁴ is an organic group of the following Formula (2-1) or (2-2):

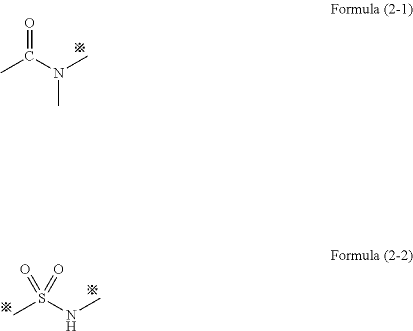

and is bonded to the silicon atom via an Si—C bond;
R⁵ is an alkyl group, an aryl group, a halogenated alkyl group, a halogenated aryl group, an alkenyl group, or an organic group having an epoxy group, an acryloyl group, a methacryloyl group, a mercapto group, an amino group, or a cyano group, and is bonded to the silicon atom via an Si—C bond;
R⁶ is an alkoxy group, an acyloxy group, or a halogen atom;
a is an integer of 1, b is an integer of 0 or 1, and a +b is an integer of 1 or 2; and
* is a site of bonding to the silicon atom directly or via a linking group].

A seventh aspect of the present invention is the composition for forming a silicon-containing resist underlayer film according to the first aspect, wherein the polysiloxane is a cohydrolysis condensate of a hydrolyzable silane containing a silane of Formula (1), a silane of Formula (2), and an additional silane, and the additional silane is at least one silane selected from the group consisting of a silane of the following Formula (3):

R⁷ₐSi(R⁸)₄₋ₐ Formula (3)

(wherein R⁷ is an alkyl group, an aryl group, a halogenated alkyl group, a halogenated aryl group, an alkenyl group, or an organic group having an epoxy group, an acryloyl group, a methacryloyl group, a mercapto group, or a cyano group, and is bonded to the silicon atom via an Si—C bond; R⁸ is an alkoxy group, an acyloxy group, or a halogen atom; and a is an integer of 0 to 3) and a silane of the following Formula (4):

[R⁹_{c}Si(R¹⁰)_{3-c}]₂Y_{b} Formula (4)

(wherein R⁹ is an alkyl group and is bonded to the silicon atom via an Si—C bond; R¹⁰ is an alkoxy group, an acyloxy group, or a halogen group; Y is an alkylene group or an arylene group; b is an integer of 0 or 1; and c is an integer of 0 or 1).

An eighth aspect of the present invention is the composition for forming a silicon-containing resist underlayer film according to any one of the first to seventh aspects, wherein the composition further comprises a photoacid generator.

A ninth aspect of the present invention is the composition for forming a silicon-containing resist underlayer film according to any one of the first to eighth aspects, wherein the composition further comprises a metal oxide.

A tenth aspect of the present invention is the composition for forming a silicon-containing resist underlayer film according to any one of the first to ninth aspects, wherein the hydrogen peroxide-containing chemical is an aqueous solution containing ammonia and hydrogen peroxide, an aqueous solution containing hydrochloric acid and hydrogen peroxide, an aqueous solution containing sulfuric acid and hydrogen peroxide, or an aqueous solution containing hydrofluoric acid and hydrogen peroxide.

An eleventh aspect of the present invention is a method for producing a resist underlayer film, the method comprising applying the composition for forming a resist underlayer film according to any one of the first to tenth aspects onto a semiconductor substrate; and baking the composition.

A twelfth aspect of the present invention is a method for producing a semiconductor device, the method comprising a step of applying the composition for forming a resist underlayer film according to any one of the first to tenth aspects onto a semiconductor substrate, followed by baking the composition, to thereby form a resist underlayer film; a step of applying a resist composition onto the underlayer film to thereby form a resist film; a step of exposing the resist film to light; a step of developing the resist after the light exposure to thereby form a resist pattern; a step of etching the resist underlayer film with the resist pattern; a step of processing the semiconductor substrate with the patterned resist and resist underlayer film; and a step of removing a mask layer with a hydrogen peroxide-containing chemical.

A thirteenth aspect of the present invention is a method for producing a semiconductor device, the method comprising a step of forming an organic underlayer film on a semiconductor substrate; a step of applying the composition for forming a resist underlayer film according to any one of the first to tenth aspects onto the organic underlayer film, followed by baking the composition, to thereby form a resist underlayer film; a step of applying a resist composition onto the resist underlayer film to thereby form a resist film; a step of exposing the resist film to light; a step of developing the resist after the light exposure to thereby form a resist pattern; a step of etching the resist underlayer film with the resist pattern; a step of etching the organic underlayer film with the patterned resist underlayer film; a step of processing the semiconductor substrate with the patterned organic underlayer film; and a step of removing a mask layer with a hydrogen peroxide-containing chemical.

A fourteenth aspect of the present invention is the method for producing a semiconductor device according to the twelfth or thirteenth aspect, wherein the substrate is processed by etching or ion implantation.

A fifteenth aspect of the present invention is the method for producing a semiconductor device according to any one of the twelfth and thirteenth aspects, wherein the mask layer is an organic underlayer film including the resist or the resist underlayer film.

### Effects of the Invention

According to the present application, mask residues after processing of a substrate (e.g., an organic underlayer film including a resist or a resist underlayer film) can be removed with a chemical. Even silicon-containing mask residues (e.g., a silicon-containing resist underlayer film) can be readily removed with a chemical, and thus a semiconductor device can be produced while reducing damage to a substrate.

The aforementioned chemical contains hydrogen peroxide, and is an aqueous solution containing ammonia and hydrogen peroxide (SC-1 chemical), an aqueous solution containing hydrochloric acid and hydrogen peroxide (SC-2 chemical), an aqueous solution containing sulfuric acid and hydrogen peroxide (SPM chemical), or an aqueous solution containing hydrofluoric acid and hydrogen peroxide (FPM chemical). The present invention provides a resist underlayer film-forming composition that is readily removed with such a chemical.

In particular, the resist underlayer film of the present invention is effective for a step of removing a mask layer (i.e., an organic underlayer film including a resist or the resist underlayer film) with a hydrogen peroxide-containing chemical after a step of processing a semiconductor substrate by etching or ion implantation.

### Modes for Carrying Out the Invention

The present invention is directed to a composition for forming a silicon-containing resist underlayer film that is used in a step of removing a mask layer including the silicon-containing resist underlayer film with a hydrogen peroxide-containing chemical after transfer of a pattern to an underlayer by a lithography process. The composition is a silicon-containing resist underlayer film-forming composition containing a polysiloxane having a unit structure including a carbonyl group-containing functional group.

The resist underlayer film-forming composition of the present invention contains a hydrolysis condensate (polymer) of a hydrolyzable silane of Formula (1) and a solvent. The composition may contain a hydrolysis condensate of a hydrolyzable silane consisting of a combination of a hydrolyzable silane of Formula (1) and a hydrolyzable silane of Formula (2), a combination of a hydrolyzable silane of Formula (1), a hydrolyzable silane of Formula (2), and a hydrolyzable silane of Formula (3), a combination of a hydrolyzable silane of Formula (1) and a hydrolyzable silane of Formula (3), or a combination of a hydrolyzable silane of Formula (1), a hydrolyzable silane of Formula (2), a hydrolyzable silane of Formula (3), and a hydrolyzable silane of Formula (4).

The composition may contain, as optional components, an acid, water, an alcohol, a curing catalyst, an acid generator, another organic polymer, a light-absorbing compound, and a surfactant.

The resist underlayer film-forming composition of the present invention has a solid content of, for example, 0.1% by mass to 50% by mass, 0.1% by mass to 30% by mass, or 0.1% by mass to 25% by mass. The “solid content” as used herein refers to a value obtained by subtracting the amount of the solvent component from the total amount of all components of the resist underlayer film-forming composition.

The amounts of the hydrolyzable silane, the hydrolysis product thereof, and the hydrolysis condensate thereof in the solid content is 20% by mass or more, for example, 50% by mass to 100% by mass, 60% by mass to 100% by mass, or 70% by mass to 100% by mass.

The composition may contain a mixture of the hydrolysis condensate with a silane compound and a partial-hydrolysis product prepared through incomplete hydrolysis of the hydrolyzable silane during preparation of the hydrolysis condensate. The condensate is a polymer having a polysiloxane structure.

The hydrolyzable silane used in the present invention may contain a silane of Formula (1).

In Formula (1), R¹ is an organic group of Formula (1-1), (1-2), (1-3), (1-4), (1-5), or (1-6) and is bonded to the silicon atom via an Si—C bond.

In Formulae (1-1), (1-2), and (1-3), T¹ and T⁴ are each an alkylene group or a cyclic alkylene group; T² is an alkyl group; T³ is a cyclic alkylene group; and n is an integer of 1 or 2, and each of these groups is bonded to the silicon atom via an Si—C bond.

In Formulae (1-4), (1-5), and (1-6), T¹¹, T¹⁵, and T¹⁸ are each an alkylene group, a cyclic alkylene group, an alkenylene group, an arylene group, a sulfur atom, an oxygen atom, an oxycarbonyl group, an amide group, a secondary amino group, or any combination of these; T¹², T¹³, T¹⁴, T¹⁶, T¹⁷, T¹⁹, and T²⁰ are each a hydrogen atom or an alkyl group; and T²¹ is an alkylene group.

In Formula (1), R² is an alkyl group, an aryl group, a halogenated alkyl group, a halogenated aryl group, an alkenyl group, or an organic group having an epoxy group, an acryloyl group, a methacryloyl group, a mercapto group, an amino group, or a cyano group, and is bonded to the silicon atom via an Si—C bond. In Formula (1), R³ is an alkoxy group, an acyloxy group, or a halogen group; a is an integer of 1, b is an integer of 0 or 1, and a+b is an integer of 1 or 2; and * is a site of bonding to the silicon atom directly or via a linking group.

The hydrolyzable silane used in the present invention may contain a silane of Formula (1) and a silane of Formula (2).

In Formula (2), R⁴ is an organic group of Formula (2-1) or (2-2) and is bonded to the silicon atom via an Si—C bond.

In Formula (2), R⁵ is an alkyl group, an aryl group, a halogenated alkyl group, a halogenated aryl group, an alkenyl group, or an organic group having an epoxy group, an acryloyl group, a methacryloyl group, a mercapto group, an amino group, or a cyano group, and is bonded to the silicon atom via an Si—C bond. In Formula (2), R⁶ is an alkoxy group, an acyloxy group, or a halogen group; a is an integer of 1, b is an integer of 0 or 1, and a+b is an integer of 1 or 2; and * is a site of bonding to the silicon atom directly or via a linking group.

The hydrolyzable silane used in the present invention may contain a silane of Formula (1), a silane of Formula (2), and an additional silane, and the additional silane may be at least one silane selected from the group consisting of silanes of Formulae (3) and (4).

In a silane of Formula (3), R⁷ is an alkyl group, an aryl group, a halogenated alkyl group, a halogenated aryl group, an alkenyl group, or an organic group having an epoxy group, an acryloyl group, a methacryloyl group, a mercapto group, or a cyano group, and is bonded to the silicon atom via an Si—C bond; R⁸ is an alkoxy group, an acyloxy group, or a halogen atom; and a is an integer of 0 to 3.

In a silane of Formula (4), R⁹ is an alkyl group and is bonded to the silicon atom via an Si—C bond; R¹⁰ is an alkoxy group, an acyloxy group, or a halogen group; Y is an alkylene group or an arylene group; b is an integer of 0 or 1; and c is an integer of 0 or 1.

The aforementioned alkyl group is a linear or branched alkyl group having a carbon atom number of 1 to 10. Examples of the alkyl group include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

The alkyl group may be a cyclic alkyl group. Examples of cyclic alkyl groups having a carbon atom number of 1 to 10 include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

The alkylene group may be, for example, an alkylene group derived from any of the aforementioned alkyl groups. Examples of such an alkylene group include methylene group derived from methyl group, ethylene group derived from ethyl group, and propylene group derived from propyl group.

The alkenyl group is a C₂₋₁₀ alkenyl group, and examples thereof include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

The alkenylene group is, for example, an alkenylene group derived from any of the aforementioned alkenyl groups.

The aryl group is, for example, a C₆₋₂₀ aryl group, and examples thereof include phenyl group, o-methylphenyl group, m-methylphenyl group, p-methylphenyl group, o-chlorophenyl group, m-chlorophenyl group, p-chlorophenyl group, o-fluorophenyl group, p-mercaptophenyl group, o-methoxyphenyl group, p-methoxyphenyl group, p-aminophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, and 9-phenanthryl group.

The arylene group is, for example, an arylene group derived from any of the aforementioned aryl groups.

The arylene group is, for example, an organic group prepared by substitution of such an arylene group with a halogen atom (e.g., fluorine, chlorine, bromine, or iodine).

The use of a sulfur atom can form a sulfide bond. The use of an oxygen atom can form an ether bond. The use of an oxycarbonyl group can form an ester bond. The use of an amide group can form an amide bond. The use of a secondary amino group can form an amino group. These functional groups can be combined with the aforementioned examples to thereby form the respective bonds.

Examples of the organic group having an epoxy group include glycidoxymethyl, glycidoxyethyl, glycidoxypropyl, glycidoxybutyl, and epoxycyclohexyl.

Examples of the organic group having an acryloyl group include acryloylmethyl, acryloylethyl, and acryloylpropyl.

Examples of the organic group having a methacryloyl group include methacryloylmethyl, methacryloylethyl, and methacryloylpropyl.

Examples of the organic group having a mercapto group include ethylmercapto, butylmercapto, hexylmercapto, and octylmercapto.

Examples of the organic group having a cyano group include cyanoethyl and cyanopropyl.

The aforementioned C₁₋₂₀ alkoxy group is, for example, an alkoxy group having a linear, branched, or cyclic alkyl moiety having a carbon atom number of 1 to 20. Examples of the alkoxy group include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group. Examples of the cyclic alkoxy group include cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Examples of the aforementioned C₂₋₂₀ acyloxy group include methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

Examples of the aforementioned halogen atom include fluorine, chlorine, bromine, and iodine.

Examples of the hydrolyzable silane of Formula (1) are as follows.

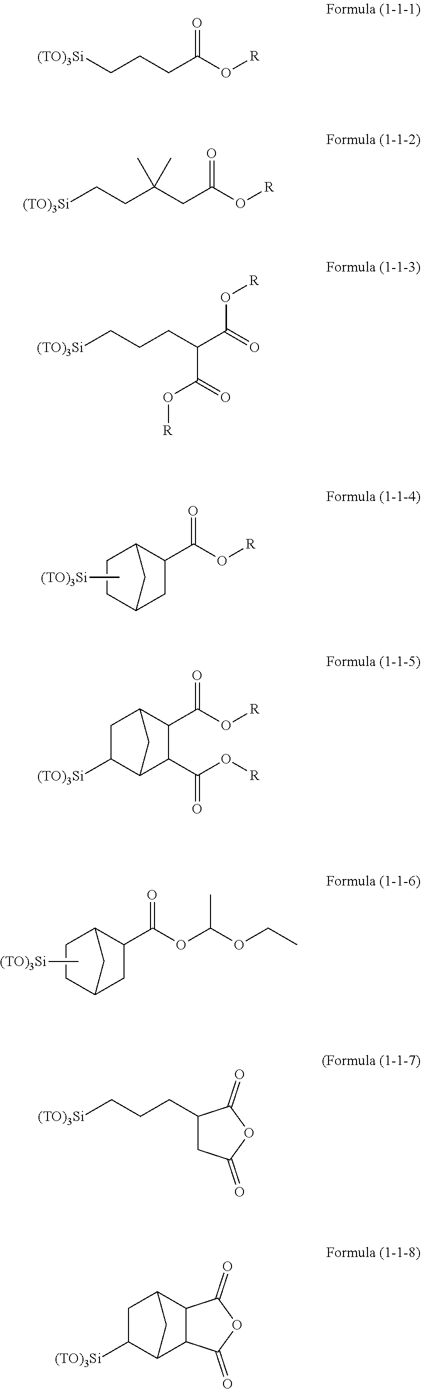

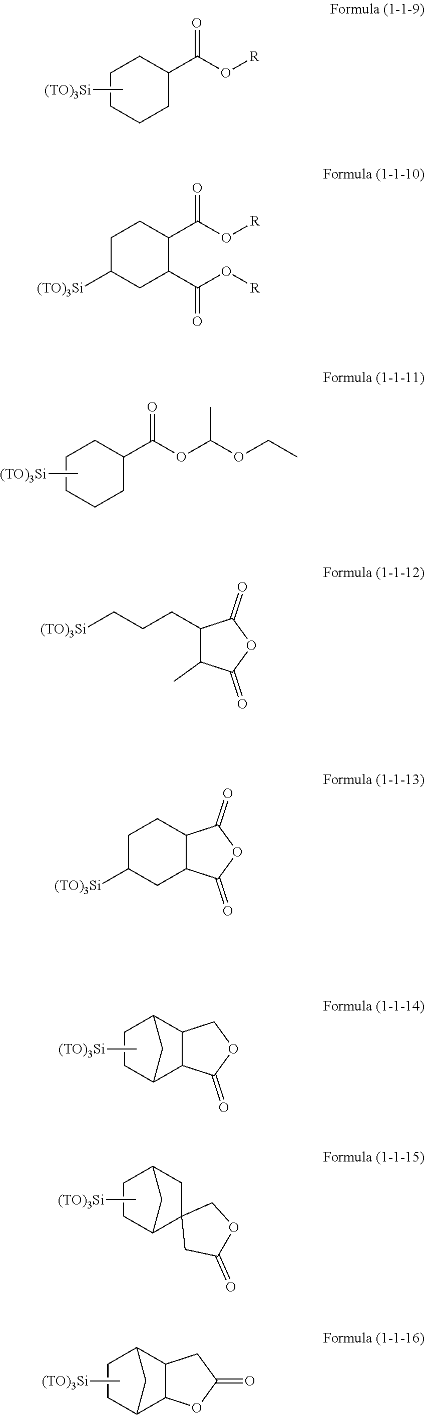

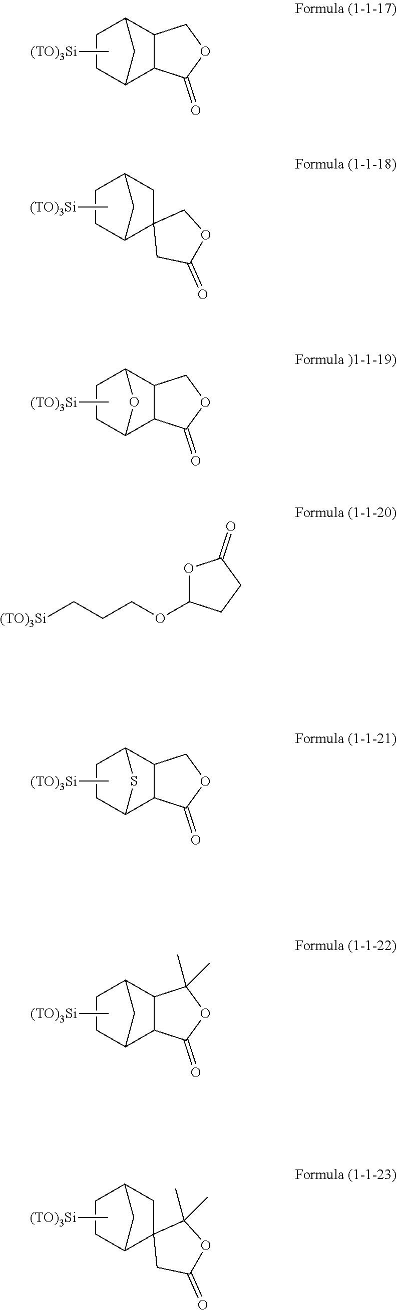

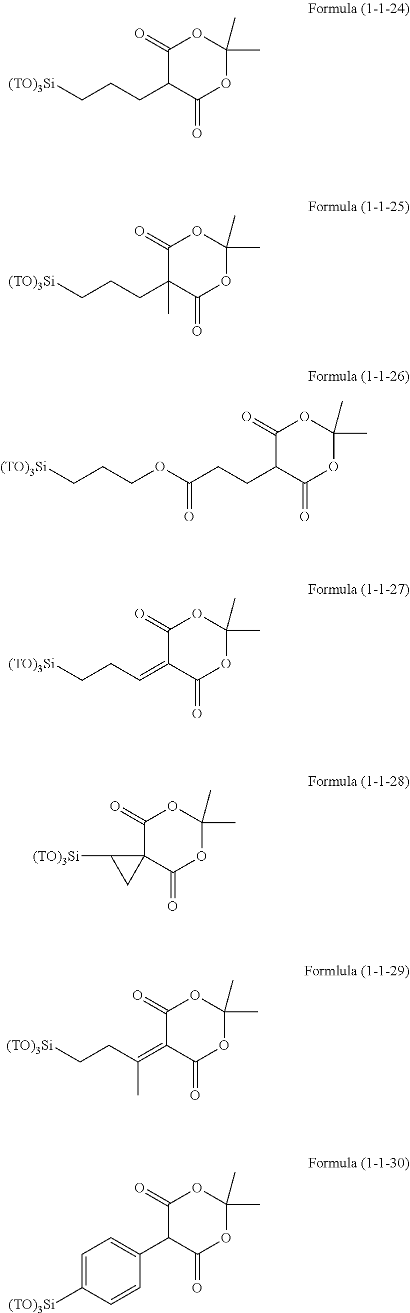

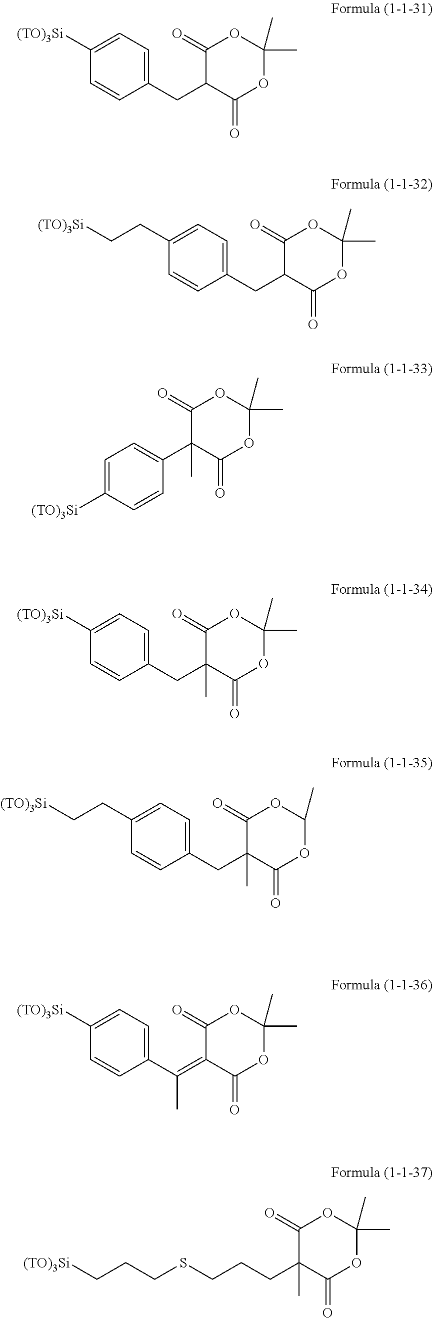

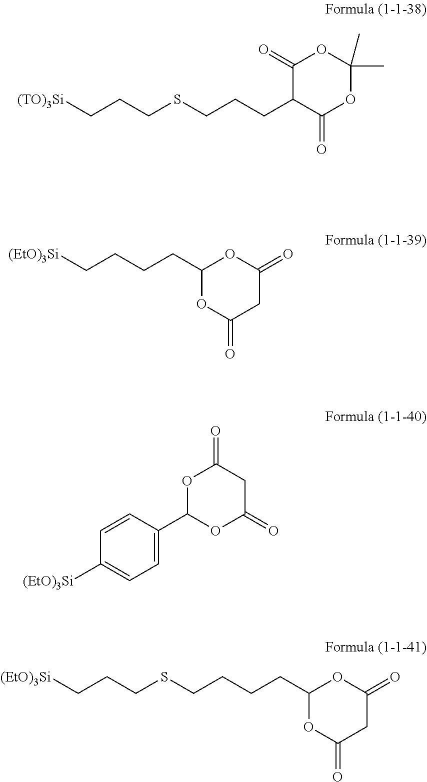

Examples of the hydrolyzable silane of Formula (2) are as follows.

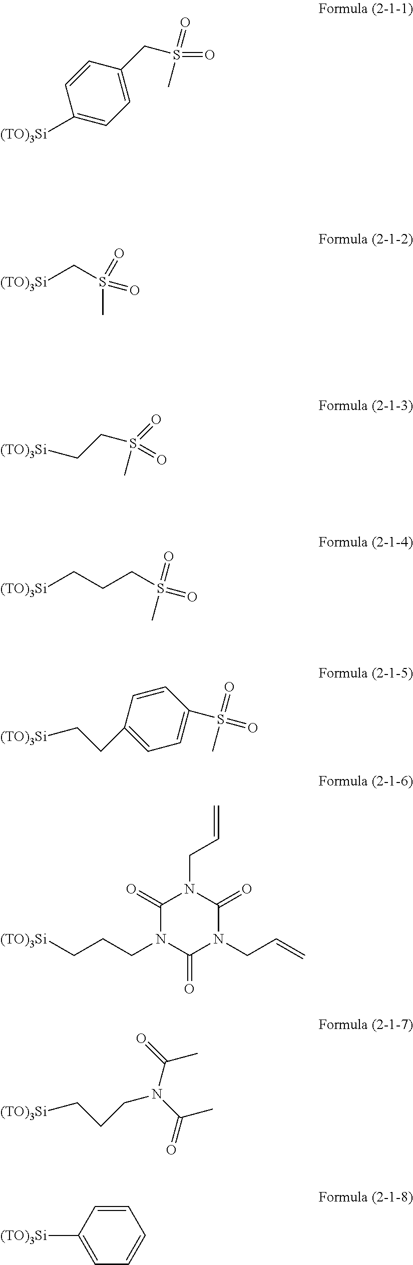

T in the aforementioned formulae is an alkyl group that may be any of the above-exemplified alkyl groups. The alkyl group is preferably, for example, a methyl group or an ethyl group.

Examples of the silicon-containing compound of Formula (3) include tetramethoxysilane, tetrachlorosilane, tetraacetoxysilane, tetraethoxysilane, tetra-n-propoxysilane, tetraisopropoxysilane, tetra-n-butoxysilane, tetraacetoxysilane, methyltrimethoxysilane, methyltrichlorosilane, methyltriacetoxysilane, methyltripropoxysilane, methyltriacetixysilane, methyltributoxysilane, methyltripropoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltrichlorosilane, vinyltriacetoxysilane, vinyltriethoxysilane, vinyltriacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, isopropoxyphenyltrimethoxysilane, isopropoxyphenyltriethoxysilane, isopropoxyphenyltriacetoxysilane, isopropoxyphenyltrichlorosilane, isopropoxybenzyltrimethoxysilane, isopropoxybenzyltriethoxysilane, isopropoxybenzyltriacetoxysilane, isopropoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, chloromethyltrimethoxysilane, chloromethyltriethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, and methylvinyldiethoxysilane.

The aryl group of R⁷ in Formula (3) is preferably a substituted aryl group; for example, a substituted phenyl group. Examples of the silane having such a substituted phenyl group (e.g., an alkoxyphenyl group, or an acyloxyphenyl group, or an organic group containing it) are as follows.

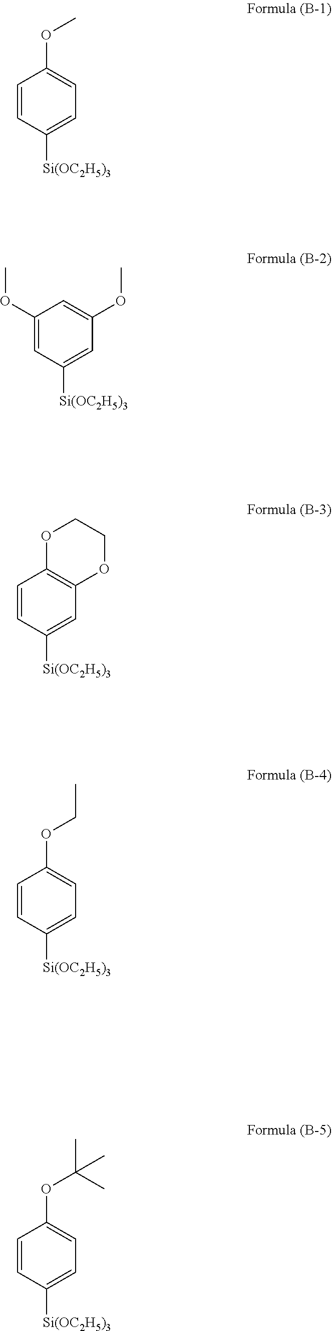

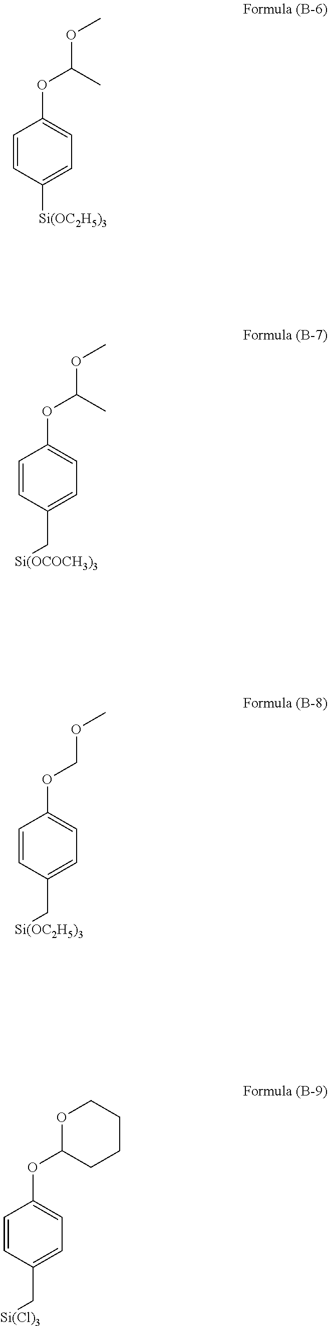

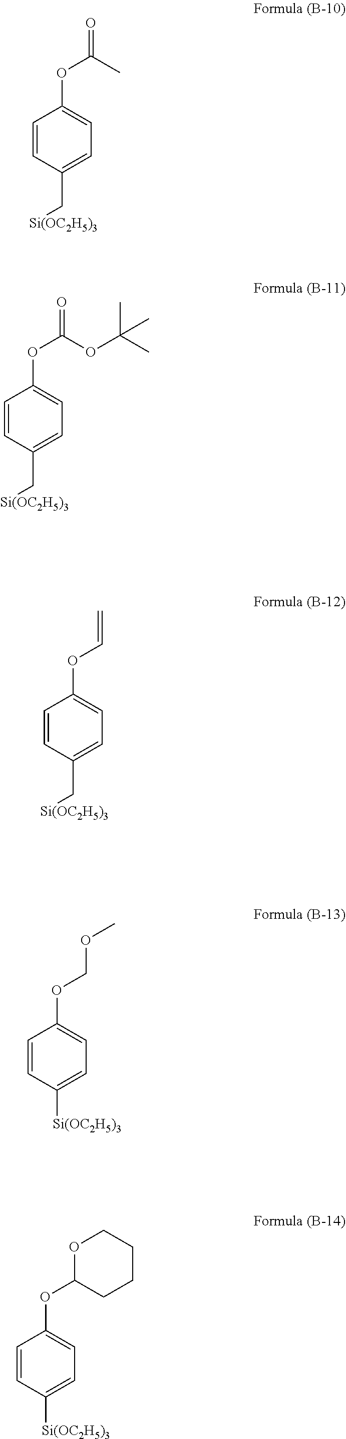

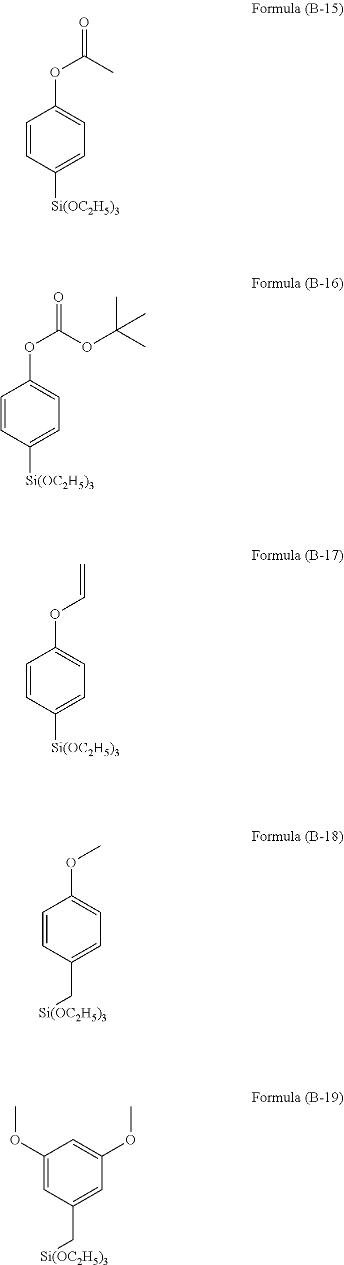

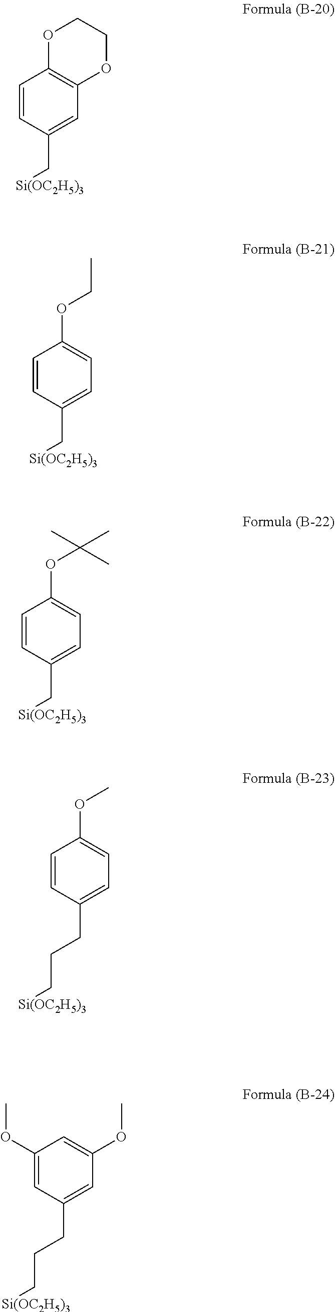

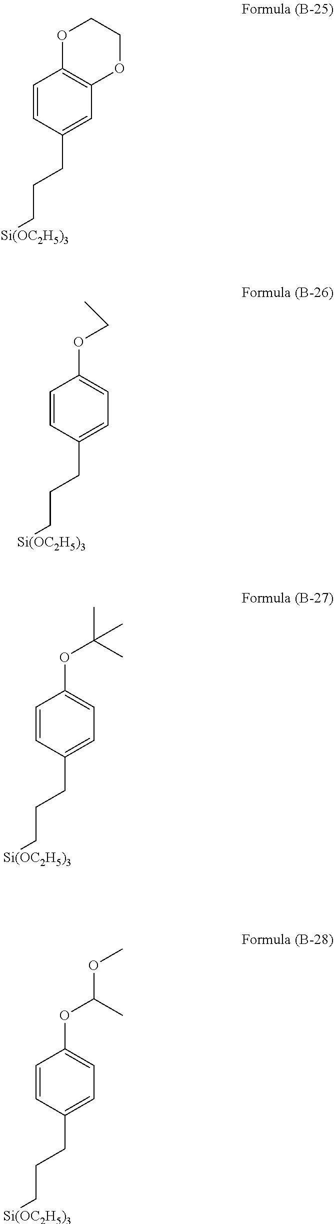

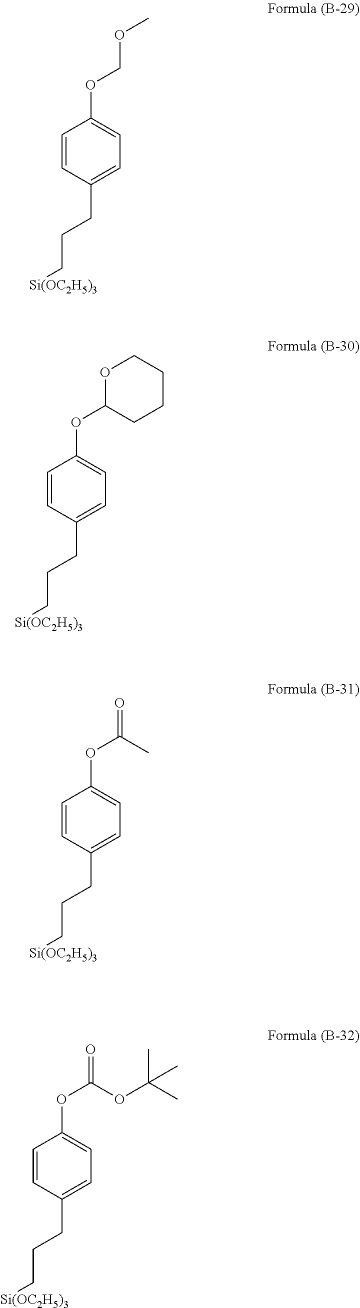

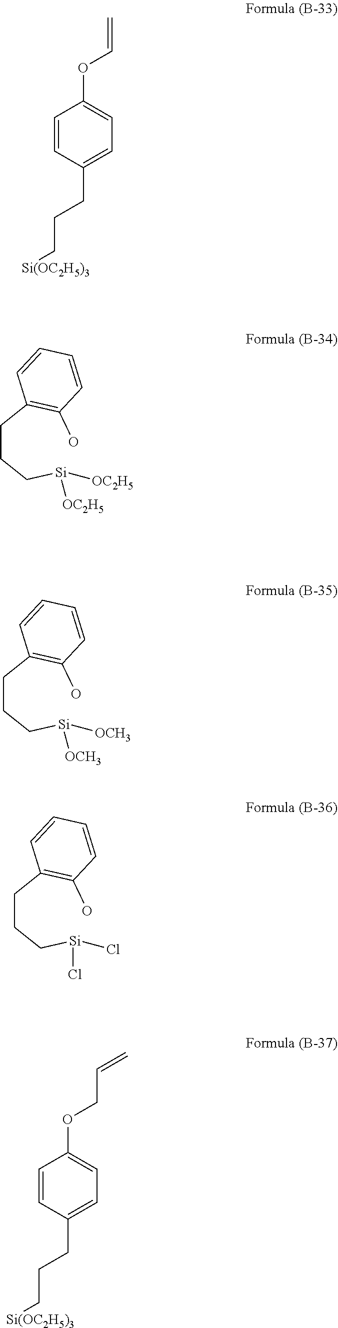

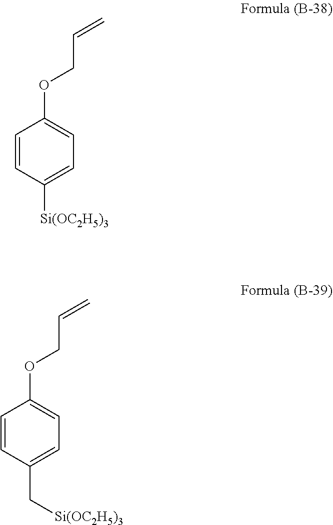

Examples of the silicon-containing compound of Formula (4) include methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxydisilane, bistriethoxydisilane, bisethyldiethoxydisilane, and bismethyldimethoxydisilane.

Specific examples of the hydrolysis condensate used in the present invention are as follows.

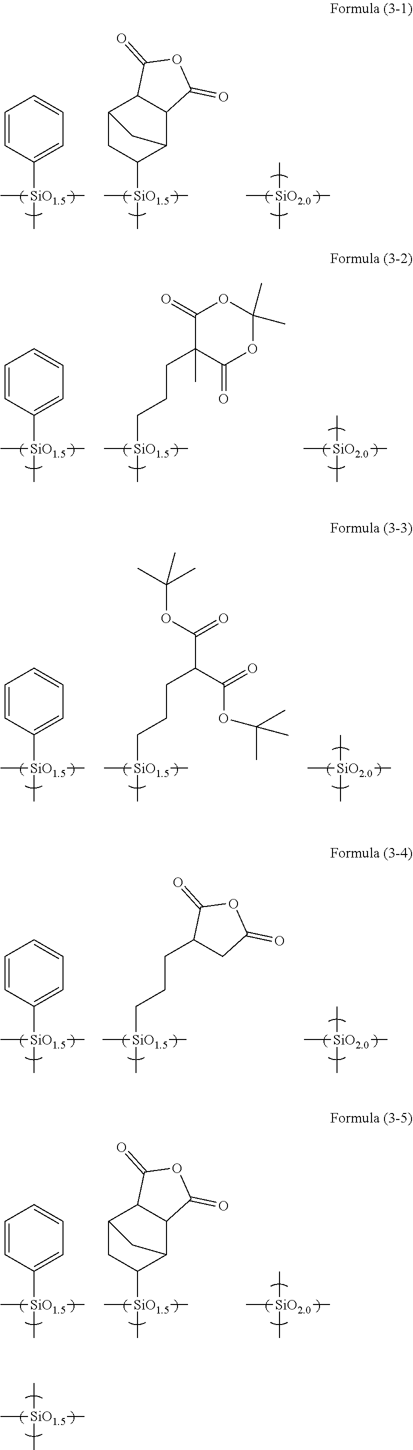

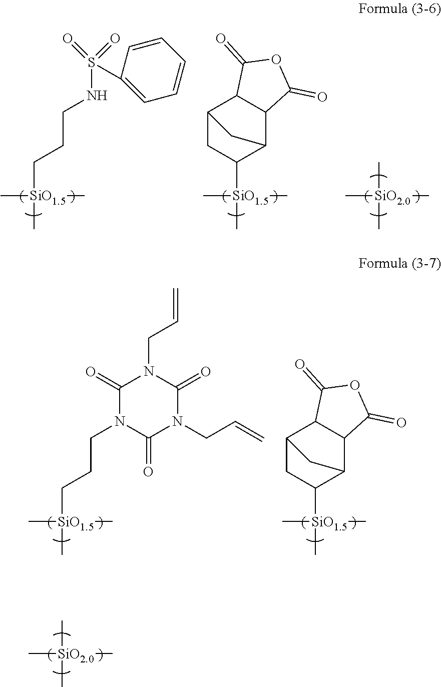

The hydrolysis condensate (polyorganosiloxane) of the aforementioned hydrolyzable silane has a weight average molecular weight of 1,000 to 1,000,000 or 1,000 to 100,000. The molecular weight is determined by GPC analysis in terms of polystyrene.

The GPC analysis can be performed under, for example, the following conditions: GPC apparatus (trade name: HLC-8220GPC, available from Tosoh Corporation), GPC columns (trade name: Shodex KF803L, KF802, and KF801, available from Showa Denko K.K.), a column temperature of 40° C., tetrahydrofuran serving as an eluent (elution solvent), a flow amount (flow rate) of 1.0 ml/min, and polystyrene (available from Showa Denko K.K.) as a standard sample.

For the hydrolysis of an alkoxysilyl group, an acyloxysilyl group, or a halogenated silyl group, 0.5 mol to 100 mol (preferably 1 mol to 10 mol) of water is used per mol of the hydrolyzable group.

Furthermore, 0.001 mol to 10 mol (preferably 0.001 mol to 1 mol) of a hydrolysis catalyst may be used per mol of the hydrolyzable group.

The reaction temperature for hydrolysis and condensation is generally 20° C. to 80° C.

The hydrolysis may be completely or partially performed. Thus, a hydrolysis product or a monomer may remain in the resultant hydrolysis condensate.

A catalyst may be used for the hydrolysis and condensation.

Examples of the hydrolysis catalyst include metal chelate compounds, organic acids, inorganic acids, organic bases, and inorganic bases.

Examples of the metal chelate compound serving as the hydrolysis catalyst include titanium chelate compounds, such as triethoxy mono(acetylacetonato)titanium; zirconium chelate compounds, such as triethoxy mono(acetylacetonato)zirconium; and aluminum chelate compounds, such as tris(acetylacetonato)aluminum.

Examples of the organic acid serving as the hydrolysis catalyst include acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid serving as the hydrolysis catalyst include hydrochloric acid, nitric acid, sulfuric acid, hydrofluoric acid, and phosphoric acid.

Examples of the organic base serving as the hydrolysis catalyst include pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, and tetramethylammonium hydroxide. Examples of the inorganic base include ammonia, sodium hydroxide, potassium hydroxide, barium hydroxide, and calcium hydroxide. Among these catalysts, a metal chelate compound, an organic acid, and an inorganic acid are preferred. These catalysts may be used alone or in combination of two or more species.

Examples of the organic solvent used for the hydrolysis include aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and trimethylbenzene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, pentanediol-2,4, 2-methylpentanediol-2,4, hexanediol-2,5, heptanediol-2,4, 2-ethylhexanediol-1,3, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, propylene glycol monomethyl ether acetate, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methylpyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents may be used alone or in combination of two or more species.

Particularly preferred are ketone solvents, such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone, in view of the preservation stability of the resultant solution.

In addition, bisphenol S or a bisphenol S derivative may be used as an additive. The amount of bisphenol S or a bisphenol S derivative is 0.01 parts by mass to 20 parts by mass, 0.01 parts by mass to 10 parts by mass, or 0.01 parts by mass to 5 parts by mass relative to 100 parts by mass of the polyorganosiloxane.

Preferred examples of the bisphenol S or the bisphenol S derivative are as follows.

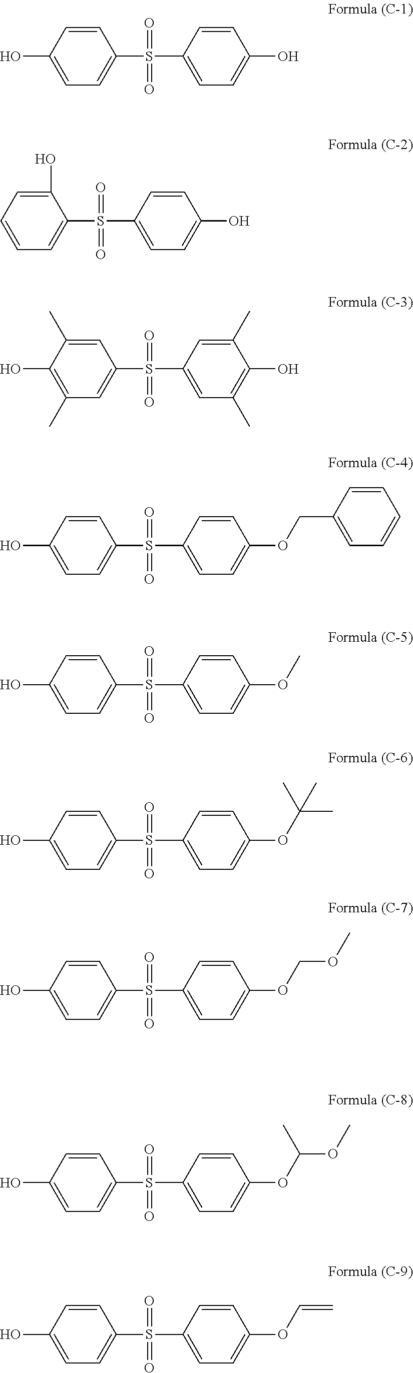

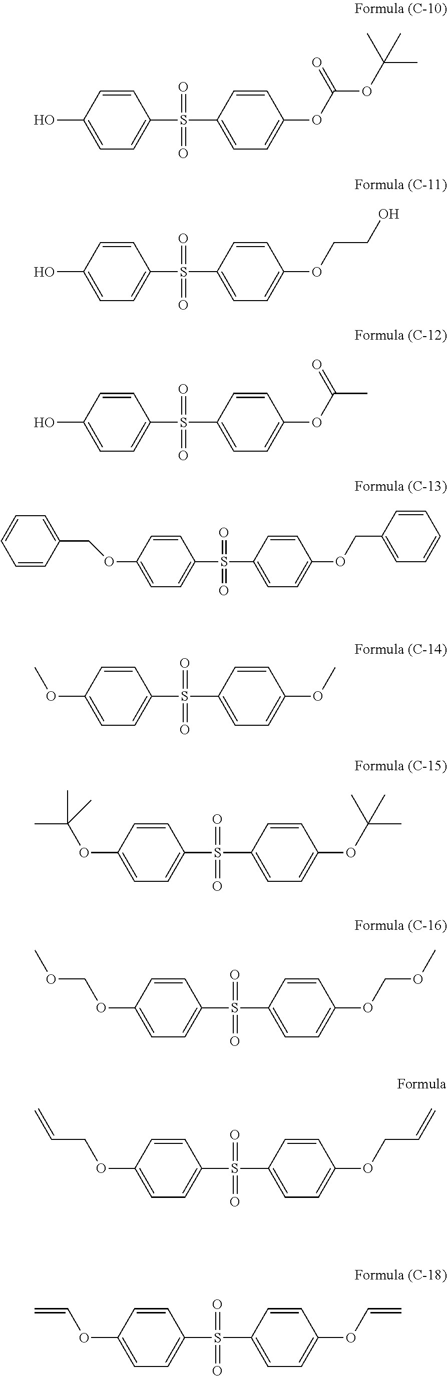

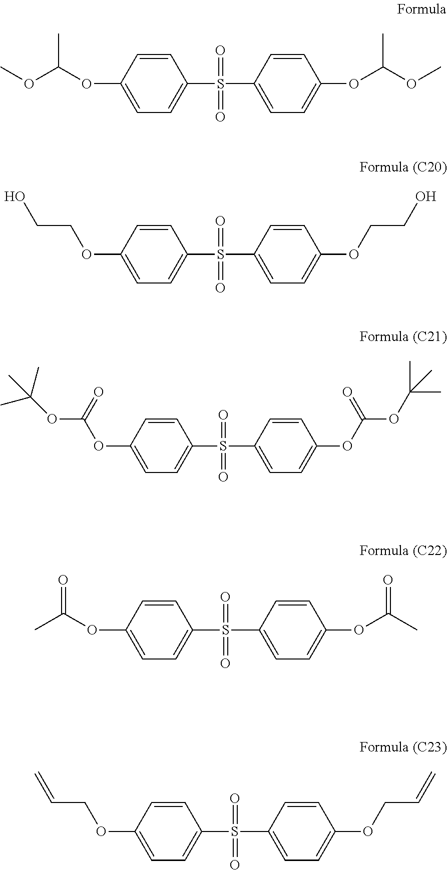

The resist underlayer film-forming composition of the present invention may contain a curing catalyst. The curing catalyst plays its own role during heating and 5 curing of a coating film containing a polyorganosiloxane composed of a hydrolysis condensate.

The curing catalyst may be an ammonium salt, a phosphine, a phosphonium salt, or a sulfonium salt.

Examples of the ammonium salt include:
a quaternary ammonium salt having a structure of the following Formula (D-1):

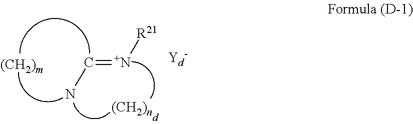

(wherein m is an integer of 2 to 11; n_{d} is an integer of 2 or 3; R²¹ is an alkyl group or an aryl group; and Y_{d}⁻ is an anion);
a quaternary ammonium salt having a structure of the following Formula (D-2):

R²²R²³R²⁴R²⁵N⁺Y_{d}⁻ Formula (D-2)

(wherein R²², R²³, R²⁴, and R²⁵ are each an alkyl group or an aryl group; N is a nitrogen atom; Y_{d}⁻ is an anion; and each of R²², R²³, R²⁴, and R²⁵ is bonded to the nitrogen atom via a C—N bond);
a quaternary ammonium salt having a structure of the following Formula (D-3):

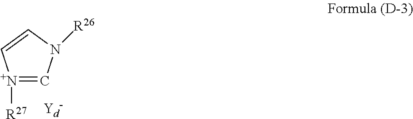

(wherein R²⁶ and R²⁷ are each an alkyl group or an aryl group; and Y_{d}⁻ is an anion);
a quaternary ammonium salt having a structure of the following Formula (D-4):

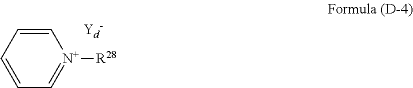

(wherein R²⁸ is an alkyl group or an aryl group; and Y_{d}⁻ is an anion);
a quaternary ammonium salt having a structure of the following Formula (D-5):

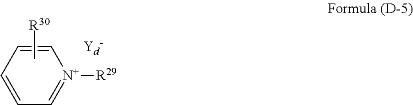

(wherein R²⁹ and R³⁰ are each an alkyl group or an aryl group; and Y_{d}⁻ is an anion); and
a tertiary ammonium salt having a structure of the following Formula (D-6):

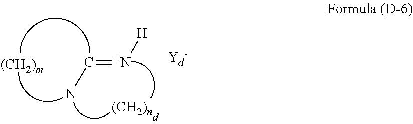

(wherein m is an integer of 2 to 11; n is an integer of 2 or 3; His a hydrogen atom; and Y_{d}⁻ is an anion).

Examples of the phosphonium salt include a quaternary phosphonium salt of the following Formula (D-7):

R³¹R³²R³³R³⁴P⁺Y_{d}⁻ Formula (D-7)

(wherein R³¹, R³², R³³, and R³⁴ are each an alkyl group or an aryl group; P is a phosphorus atom; Y_{d}⁻ is an anion; and each of R³¹, R³², R³³, and R³⁴ is bonded to the phosphorus atom via a C—P bond).

Examples of the sulfonium salt include a tertiary sulfonium salt of the following Formula (D-8):

R¹⁵R¹⁶R¹⁷S⁺Y_{d}⁻ Formula (D-8)

(wherein R¹⁵, R¹⁶, and R¹⁷ are each an alkyl group or an aryl group; S is a sulfur atom; Y_{d}⁻ is an anion; and each of R¹⁵, R¹⁶, and R¹⁷ is bonded to the sulfur atom via a C—S bond).

The compound of Formula (D-1) is a quaternary ammonium salt derived from an amine. In Formula (D-1), m is an integer of 2 to 11, and n_{d} is an integer of 2 or 3. R²¹ of the quaternary ammonium salt is a C₁₋₁₈ alkyl or aryl group, preferably a C₂₋₁₀ alkyl or aryl group. Examples of R²¹ include linear alkyl groups, such as ethyl group, propyl group, and butyl group, benzyl group, cyclohexyl group, cyclohexylmethyl group, and dicyclopentadienyl group. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻).

The compound of Formula (D-2) is a quaternary ammonium salt having a structure of R²²R²³R²⁴R²⁵N⁺Y_{d}⁻. R²², R²³, R²⁴, and R²⁵ of the quaternary ammonium salt are each a C₁₋₁₈ alkyl or aryl group, or a quaternary ammonium compound bonded to the nitrogen atom via a C—N bond. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. In Formula (D-3), R²⁶ and R²⁷ are each a C₁₋₁₈ alkyl or aryl group, and the total number of carbon atoms of R²⁶ and R²⁷ is preferably 7 or more. Examples of R²⁶ include methyl group, ethyl group, propyl group, phenyl group, and benzyl group. Examples of R²⁷ include benzyl group, octyl group, and octadecyl group. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). Although this compound is commercially available, the compound can be produced through, for example, reaction between an imidazole compound (e.g., 1-methylimidazole or 1-benzylimidazole) and an alkyl or aryl halide (e.g., benzyl bromide or methyl bromide).

The compound of Formula (D-4) is a quaternary ammonium salt derived from pyridine. In Formula (D-4), R²⁸ is a C₁₋₁₈ alkyl or aryl group, preferably a C₄₋₁₈ alkyl or aryl group. Examples of R²⁸ include butyl group, octyl group, benzyl group, and lauryl group. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). Although this compound is commercially available, the compound can be produced through, for example, reaction between pyridine and an alkyl or aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. In Formula (D-5), R²⁹ is a C₁₋₁₈ alkyl or aryl group, preferably a C₄₋₁₈ alkyl or aryl group. Examples of R²⁹ include methyl group, octyl group, lauryl group, and benzyl group. R³⁰ is a C₁₋₁₈ alkyl or aryl group, and, for example, R³⁰ is a methyl group when the compound is a quaternary ammonium salt derived from picoline. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). Although this compound is commercially available, the compound can be produced through, for example, reaction between a substituted pyridine (e.g., picoline) and an alkyl or aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine. In Formula (D-6), m is an integer of 2 to 11, and n_{d} is an integer of 2 or 3. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). The compound can be produced through, for example, reaction between an amine and a weak acid, such as a carboxylic acid or phenol. Examples of the carboxylic acid include formic acid and acetic acid. When formic acid is used, the anion (Y_{d}⁻) is (HCOO⁻). When acetic acid is used, the anion (Y_{d}⁻) is (CH₃COO⁻). When phenol is used, the anion (Y_{d}⁻) is (C₆H₅O⁻).

The compound of Formula (D-7) is a quaternary phosphonium salt having a structure of R³¹R₃₂R³³R³⁴P⁺Y_{d}⁻. R³¹, R³², R³³, and R³⁴ are each a C₁₋₁₈ alkyl or aryl group, or a silane compound bonded to the silicon atom via an Si—C bond. Three of the four substituents R³¹ to R³⁴ are preferably a phenyl group or a substituted phenyl group, such as a phenyl group or a tolyl group. The remaining one substituent is a C₁₋₁₈ alkyl or aryl group, or a silane compound bonded to the silicon atom via an Si—C bond. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halides and tetra-n-propylphosphonium halides; trialkylbenzylphosphonium halides, such as triethylbenzylphosphonium halides; triphenylmonoalkylphosphonium halides, such as triphenylmethylphosphonium halides and triphenylethylphosphonium halides; triphenylbenzylphosphonium halides; tetraphenylphosphonium halides; tritolylmonoarylphosphonium halides; and tritolylmonoalkylphosphonium halides (wherein the halogen atom is a chlorine atom or a bromine atom). Particularly preferred are triphenylmonoalkylphosphonium halides, such as triphenylmethylphosphonium halides and triphenylethylphosphonium halides; triphenylmonoarylphosphonium halides, such as triphenylbenzylphosphonium halides; tritolylmonoarylphosphonium halides, such as tritolylmonophenylphosphonium halides; and tritolylmonoalkylphosphonium halides, such as tritolylmonomethylphosphonium halides (wherein the halogen atom is a chlorine atom or a bromine atom).

Examples of the phosphine include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R¹⁵R¹⁶R¹⁷S⁺Y_{d}⁻. R¹⁵, R¹⁶, and R¹⁷ are each a C₁₋₁₈ alkyl or aryl group, or a silane compound bonded to the silicon atom via an Si—C bond. Two of the three substituents R¹⁵ to R¹⁷ are preferably a phenyl group or a substituted phenyl group, such as a phenyl group or a tolyl group. The remaining one substituent is a C₁₋₁₈ alkyl or aryl group. Examples of the anion (Y_{d}⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). This compound is commercially available, and examples of the compound include tetraalkylsulfonium halides, such as tri-n-butylsulfonium halides and tri-n-propylsulfonium halides; trialkylbenzylsulfonium halides, such as diethylbenzylsulfonium halides; diphenylmonoalkylsulfonium halides, such as diphenylmethylsulfonium halides and diphenylethylsulfonium halides; triphenylsulfonium halides (wherein the halogen atom is a chlorine atom or a bromine atom); tetraalkylphosphonium carboxylates, such as tri-n-butylsulfonium carboxylate and tri-n-propylsulfonium carboxylate; trialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. In particular, triphenylsulfonium halides and triphenylsulfonium carboxylate are preferably used.

The amount of the curing catalyst is 0.01 parts by mass to 10 parts by mass, 0.01 parts by mass to 5 parts by mass, or 0.01 parts by mass to 3 parts by mass relative to 100 parts by mass of the polyorganosiloxane.

From a hydrolysis condensate (polymer) prepared by hydrolysis and condensation of a hydrolyzable silane with a catalyst in a solvent, alcohols (i.e., by-products), the used hydrolysis catalyst, and water can be simultaneously removed by, for example, distillation under reduced pressure. Furthermore, an acid or base catalyst used in the hydrolysis can be removed by neutralization or ion exchange. In the case of the resist underlayer film-forming composition for lithography of the present invention, an organic acid, water, an alcohol, or a combination thereof may be added to the resist underlayer film-forming composition containing the hydrolysis condensate for stabilization of the composition.

Examples of the organic acid include oxalic acid, malonic acid, methylmalonic acid, succinic acid, maleic acid, malic acid, tartaric acid, phthalic acid, citric acid, glutaric acid, citric acid, lactic acid, and salicylic acid. Of these, oxalic acid, maleic acid, etc. are preferred. The amount of the organic acid added is 0.1 parts by mass to 5.0 parts by mass relative to 100 parts by mass of the condensate (polyorganosiloxane). For example, pure water, ultrapure water, or ion-exchange water may be added to the composition, and the amount of the water added may be 1 part by mass to 20 parts by mass relative to 100 parts by mass of the resist underlayer film-forming composition.

The alcohol added to the composition is preferably an alcohol that easily dissipates by heating after the application of the composition. Examples of the alcohol include methanol, ethanol, propanol, isopropanol, and butanol. The amount of the alcohol added may be 1 part by mass to 20 parts by mass relative to 100 parts by mass of the resist underlayer film-forming composition.

The underlayer film-forming composition for lithography of the present invention may optionally contain, besides the aforementioned components, an organic polymer compound, a photoacid generator, and a surfactant.

The use of an organic polymer compound enables adjustment of, for example, the dry etching rate (the amount of a reduction in film thickness per unit time), attenuation coefficient, and refractive index of a resist underlayer film formed from the underlayer film-forming composition for lithography of the present invention.

No particular limitation is imposed on the organic polymer compound, and a variety of organic polymers may be used. For example, a polycondensation polymer and an addition polymerization polymer may be used. Examples of the usable addition polymerization polymer and polycondensation polymer include polyester, polystyrene, polyimide, acrylic polymer, methacrylic polymer, polyvinyl ether, phenol novolac, naphthol novolac, polyether, polyamide, and polycarbonate. Preferred is an organic polymer having an aromatic ring structure that functions as a light-absorbing moiety, such as a benzene ring, a naphthalene ring, an anthracene ring, a triazine ring, a quinoline ring, and a quinoxaline ring.

Examples of such an organic polymer compound include addition polymerization polymers including, as a structural unit thereof, addition polymerizable monomers, such as benzyl acrylate, benzyl methacrylate, phenyl acrylate, naphthyl acrylate, anthryl methacrylate, anthrylmethyl methacrylate, styrene, hydroxystyrene, benzyl vinyl ether, and N-phenylmaleimide; and polycondensation polymers, such as phenol novolac and naphthol novolac.

When the organic polymer compound is an addition polymerization polymer, the polymer compound may be a homopolymer or a copolymer. An addition polymerizable monomer is used for the production of the addition polymerization polymer. Examples of such an addition polymerizable monomer include acrylic acid, methacrylic acid, an acrylic ester compound, a methacrylic ester compound, an acrylamide compound, a methacrylamide compound, a vinyl compound, a styrene compound, a maleimide compound, maleic anhydride, and acrylonitrile.

When the organic polymer compound is a polycondensation polymer, the polymer is, for example, a polycondensation polymer of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Examples of the polycondensation polymer include polyesters, polyamides, and polyimides, such as polypyromellitic imide, poly(p-phenyleneterephthalamide), polybutylene terephthalate, and polyethylene terephthalate.

When the organic polymer compound contains a hydroxy group, this hydroxy group can cause a crosslinking reaction with a polyorganosiloxane.

The organic polymer compound may be a polymer compound having a weight average molecular weight of, for example, 1,000 to 1,000,000, 3,000 to 300,000, 5,000 to 200,000, or 10,000 to 100,000.

A single organic polymer compound may be used alone, or two or more organic polymer compounds may be used in combination.

When the organic polymer compound is used, the amount thereof is 1 to 200 parts by mass, 5 to 100 parts by mass, 10 to 50 parts by mass, or 20 to 30 parts by mass relative to 100 parts by mass of the condensate (polyorganosiloxane).

The resist underlayer film-forming composition of the present invention may contain an acid generator.

Examples of the acid generator include a thermal acid generator and a photoacid generator.

A photoacid generator generates an acid during the exposure of a resist. Thus, the acidity of an underlayer film can be adjusted. This is one method for adjusting the acidity of an underlayer film to the acidity of a resist serving as an upper layer of the underlayer film. Furthermore, the adjustment of the acidity of an underlayer film enables the control of the pattern shape of a resist formed as an upper layer of the underlayer film.

Examples of the photoacid generator contained in the resist underlayer film-forming composition of the present invention include an onium salt compound, a sulfonimide compound, and a disulfonyldiazomethane compound.

Examples of the onium salt compound include iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

A single photoacid generator may be used alone, or two or more photoacid generators may be used in combination.

When the photoacid generator is used, the amount thereof is 0.01 parts by mass to 5 parts by mass, 0.1 parts by mass to 3 parts by mass, or 0.5 parts by mass to 1 part by mass relative to 100 parts by mass of the condensate (polyorganosiloxane).

A surfactant effectively suppresses formation of, for example, pinholes and striations during application of the resist underlayer film-forming composition for lithography of the present invention to a substrate.

Examples of the surfactant contained in the resist underlayer film-forming composition of the present invention include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as trade names EFTOP EF301, EF303, and EF352 (available from Tohkem Products Corporation), trade names MEGAFAC F171, F173, R-08, and R-30 (available from Dainippon Ink and Chemicals, Inc.), Fluorad FC430 and FC431 (available from Sumitomo 3M Limited), trade name Asahi Guard AG710 and trade names SURFLON S-382, SC101, SC102, SC103, SC104, SC105, and SC106 (available from Asahi Glass Co., Ltd.); and Organosiloxane Polymer KP341 (available from Shin-Etsu Chemical Co., Ltd.). These surfactants may be used alone or in combination of two or more species. When the surfactant is used, the amount thereof is 0.0001 to 5 parts by mass, 0.001 to 1 part by mass, or 0.01 to 0.5 parts by mass relative to 100 parts by mass of the condensate (polyorganosiloxane).

The resist underlayer film-forming composition of the present invention may also contain, for example, a rheology controlling agent and an adhesion aid. A rheology controlling agent is effective for improving the fluidity of the underlayer film-forming composition. An adhesion aid is effective for improving the adhesion between a semiconductor substrate or a resist and an underlayer film.

No particular limitation is imposed on the solvent used in the resist underlayer film-forming composition of the present invention, so long as the solvent can dissolve the aforementioned solid component. Examples of such a solvent include methylcellosolve acetate, ethylcellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone. These solvents may be used alone or in combination of two or more species.

The use of the resist underlayer film-forming composition of the present invention will be described as follows.

The resist underlayer film-forming composition of the present invention is applied onto a substrate used for the production of a semiconductor device (e.g., a silicon wafer substrate, a silicon/silicon dioxide-coated substrate, a silicon nitride substrate, a glass substrate, an ITO substrate, a polyimide substrate, or a substrate coated with a low dielectric constant material (low-k material)) by an appropriate application method with, for example, a spinner or a coater, followed by baking of the composition, to thereby form a resist underlayer film. The baking is performed under appropriately determined conditions; i.e., a baking temperature of 80° C. to 250° C. and a baking time of 0.3 minutes to 60 minutes. Preferably, the baking temperature is 150° C. to 250° C., and the baking time is 0.5 minutes to 2 minutes. The thickness of the thus-formed underlayer film is, for example, 10 nm to 1,000 nm, 20 nm to 500 nm, 50 nm to 300 nm, or 100 nm to 200 nm.

Subsequently, for example, a photoresist layer is formed on the resist underlayer film. The photoresist layer can be formed by a well-known process; i.e., application of a photoresist composition solution onto the underlayer film, and baking of the composition. The thickness of the photoresist layer is, for example, 50 nm to 10,000 nm, 100 nm to 2,000 nm, or 200 nm to 1,000 nm.

In the present invention, an organic underlayer film can be formed on a substrate, the resist underlayer film can then be formed from the composition of the present invention on the organic underlayer film, and then the resist underlayer film can be coated with a photoresist. This process can narrow the pattern width of the photoresist. Thus, even when the photoresist is applied thinly for preventing pattern collapse, the substrate can be processed through selection of an appropriate etching gas. For example, the resist underlayer film of the present invention can be processed by using, as an etching gas, a fluorine-containing gas that achieves a significantly high etching rate for the photoresist. The organic underlayer film can be processed by using, as an etching gas, an oxygen-containing gas that achieves a significantly high etching rate for the resist underlayer film of the present invention. The substrate can be processed by using, as an etching gas, a fluorine-containing gas that achieves a significantly high etching rate for the organic underlayer film.

No particular limitation is imposed on the photoresist formed on the resist underlayer film of the present invention, so long as the photoresist is sensitive to light used for exposure. The photoresist may be either of negative and positive photoresists. Examples of the photoresist include a positive photoresist formed of a novolac resin and a 1,2-naphthoquinone diazide sulfonic acid ester; a chemically amplified photoresist formed of a binder having a group that decomposes with an acid to thereby increase an alkali dissolution rate and a photoacid generator; a chemically amplified photoresist formed of a low-molecular-weight compound that decomposes with an acid to thereby increase the alkali dissolution rate of the photoresist, an alkali-soluble binder, and a photoacid generator; and a chemically amplified photoresist formed of a binder having a group that decomposes with an acid to thereby increase an alkali dissolution rate, a low-molecular-weight compound that decomposes with an acid to thereby increase the alkali dissolution rate of the photoresist, and a photoacid generator. Specific examples of the photoresist include trade name APEX-E, available from Shipley, trade name PAR710, available from Sumitomo Chemical Company, Limited, and trade name SEPR430, available from Shin-Etsu Chemical Co., Ltd. Other examples of the photoresist include fluorine atom-containing polymer-based photoresists described in Proc. SPIE, Vol. 3999, 330-334 (2000), Proc. SPIE, Vol. 3999, 357-364 (2000), and Proc. SPIE, Vol. 3999, 365-374 (2000).

Subsequently, light exposure is performed through a predetermined mask. The light exposure may involve the use of, for example, a KrF excimer laser (wavelength: 248 nm), an ArF excimer laser (wavelength: 193 nm), and an F2 excimer laser (wavelength: 157 nm). After the light exposure, post exposure bake may optionally be performed. The post exposure bake is performed under appropriately determined conditions; i.e., a heating temperature of 70° C. to 150° C. and a heating time of 0.3 minutes to 10 minutes.

In the present invention, a resist for electron beam lithography or a resist for EUV lithography may be used instead of the photoresist. The electron beam resist may be either of negative and positive resists. Examples of the electron beam resist include a chemically amplified resist formed of an acid generator and a binder having a group that decomposes with an acid to thereby change an alkali dissolution rate; a chemically amplified resist formed of an alkali-soluble binder, an acid generator, and a low-molecular-weight compound that decomposes with an acid to thereby change the alkali dissolution rate of the resist; a chemically amplified resist formed of an acid generator, a binder having a group that decomposes with an acid to thereby change an alkali dissolution rate, and a low-molecular-weight compound that decomposes with an acid to thereby change the alkali dissolution rate of the resist; a non-chemically amplified resist formed of a binder having a group that decomposes with electron beams to thereby change an alkali dissolution rate; and a non-chemically amplified resist formed of a binder having a moiety that is cut with electron beams to thereby change an alkali dissolution rate. Also in the case of use of such an electron beam resist, a resist pattern can be formed by using electron beams as an irradiation source in the same manner as in the case of using the photoresist.

The EUV resist may be a methacrylate resin-based resist.

Subsequently, development is performed with a developer (e.g., an alkaline developer). When, for example, a positive photoresist is used, an exposed portion of the photoresist is removed to thereby form a pattern of the photoresist.

Examples of the developer include alkaline aqueous solutions, for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine. Such a developer may also contain, for example, a surfactant. The development is performed under appropriately determined conditions; i.e., a temperature of 5° C. to 50° C. and a time of 10 seconds to 600 seconds.

In the present invention, the developer may be an organic solvent. After the light exposure, the development is performed with a developer (a solvent). When, for example, a positive photoresist is used, an unexposed portion of the photoresist is removed to thereby form a pattern of the photoresist.

Examples of the developer include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Such a developer may also contain, for example, a surfactant. The development is performed under appropriately determined conditions; i.e., a temperature of 5° C. to 50° C. and a time of 10 seconds to 600 seconds.

The resultant patterned photoresist (upper layer) is used as a protective film for removing the resist underlayer film (intermediate layer) of the present invention. Subsequently, the patterned photoresist and the patterned resist underlayer film (intermediate layer) of the present invention are used as protective films for removing the organic underlayer film (lower layer). Finally, the patterned resist underlayer film (intermediate layer) of the present invention and the patterned organic underlayer film (lower layer) are used as protective films for processing the semiconductor substrate.

Specifically, a photoresist-removed portion of the resist underlayer film (intermediate layer) of the present invention is removed by dry etching to thereby expose the semiconductor substrate. The dry etching of the resist underlayer film of the present invention can be performed with any of gasses, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane. The dry etching of the resist underlayer film is preferably performed with a halogen-containing gas. In general, a photoresist formed of an organic substance is hard to remove by dry etching with a halogen-containing gas. In contrast, the resist underlayer film of the present invention, which contains numerous silicon atoms, is quickly removed by dry etching with a halogen-containing gas. Therefore, a reduction in the thickness of the photoresist in association with the dry etching of the resist underlayer film can be suppressed. Thus, the photoresist can be used in the form of thin film. The dry etching of the resist underlayer film is preferably performed with a fluorine-containing gas. Examples of the fluorine-containing gas include tetrafluoromethane (CF₄), perfluorocyclobutane (C₄F₈), perfluoropropane (C₃F₈), trifluoromethane, and difluoromethane (CH₂F₂).

Thereafter, the patterned photoresist and the patterned resist underlayer film of the present invention are used as protective films for removing the organic underlayer film. The dry etching of the organic underlayer film (lower layer) is preferably performed with an oxygen-containing gas, since the resist underlayer film of the present invention, which contains numerous silicon atoms, is less likely to be removed by dry etching with an oxygen-containing gas.

Finally, the semiconductor substrate is processed. The processing of the semiconductor substrate is preferably performed by dry etching with a fluorine-containing gas.

Examples of the fluorine-containing gas include tetrafluoromethane (CF₄), perfluorocyclobutane (C₄F₈), perfluoropropane (C₃F₈), trifluoromethane, and difluoromethane (CH₂F₂).

The processing of the substrate may be performed by ion implantation.

After the processing of the substrate, a step of removing a mask layer with a hydrogen peroxide-containing chemical is performed, to thereby produce a semiconductor device. The mask layer is an organic underlayer film including the resist or the resist underlayer film.

An organic anti-reflective coating may be formed on the resist underlayer film of the present invention before formation of the photoresist. No particular limitation is imposed on the composition used for formation of the anti-reflective coating, and the composition may be appropriately selected from anti-reflective coating compositions that have been conventionally used in a lithography process. The anti-reflective coating can be formed by a commonly used method, for example, application of the composition with a spinner or a coater, and baking of the composition.

The substrate to which the resist underlayer film-forming composition of the present invention is applied may have an organic or inorganic anti-reflective coating formed thereon by, for example, a CVD process. The underlayer film of the present invention may be formed on the anti-reflective coating.

The resist underlayer film formed from the resist underlayer film-forming composition of the present invention may absorb light used in a lithography process depending on the wavelength of the light. In such a case, the resist underlayer film can function as an anti-reflective coating having the effect of preventing reflection of light from the substrate. Furthermore, the underlayer film of the present invention can be used as, for example, a layer for preventing the interaction between the substrate and the photoresist; a layer having the function of preventing the adverse effect, on the substrate, of a material used for the photoresist or a substance generated during the exposure of the photoresist to light; a layer having the function of preventing diffusion of a substance generated from the substrate during heating and baking to the photoresist serving as an upper layer; and a barrier layer for reducing a poisoning effect of a dielectric layer of the semiconductor substrate on the photoresist layer.

The resist underlayer film formed from the resist underlayer film-forming composition can be applied to a substrate having via holes for use in a dual damascene process, and can be used as an embedding material to fill up the holes. The resist underlayer film can also be used as a planarization material for planarizing the surface of a semiconductor substrate having irregularities.

The resist underlayer film can function not only as a hard mask, but also be used as an EUV resist underlayer film for the purpose described below. Specifically, the resist underlayer film-forming composition can be used for an anti-reflective EUV resist underlayer coating capable of, without intermixing with an EUV resist, preventing the reflection, from a substrate or an interface, of exposure light undesirable for EUV exposure (wavelength: 13.5 nm); for example, the aforementioned UV or DUV (ArF laser light, KrF laser light). Thus, the reflection can be efficiently prevented in the underlayer of the EUV resist. When the resist underlayer film is used as an EUV resist underlayer film, the film can be processed in the same manner as in the photoresist underlayer film.

### EXAMPLES

### Synthesis Example 1

A 300-ml flask was charged with 20.0 g of tetraethoxysilane, 1.5 g of phenyltrimethoxysilane, 14.6 g of 5-(triethoxysilyl)hexahydro-4,7-methanoisobenzofuran-1,3-dione, and 54.2 g of acetone. While the resultant mixture was stirred with a magnetic stirrer, 9.7 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monoethyl ether was added to the aqueous solution so as to achieve solvent proportions of propylene glycol monoethyl ether 80% and propylene glycol monomethyl ether acetate 20% and a solid residue content of 13% by mass at 140° C. The resultant polymer corresponds to Formula (3-1). The polymer was found to have a weight average molecular weight Mw of 1,500 as determined by GPC in terms of polystyrene.

### Synthesis Example 2

A 300-ml flask was charged with 20.0 g of tetraethoxysilane, 1.5 g of phenyltrimethoxysilane, 14.6 g of 5-(triethoxysilyl)hexahydro-4,7-methanoisobenzofuran-1,3-dione, and 54.2 g of acetone. While the resultant mixture was stirred with a magnetic stirrer, 9.7 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether was added to the aqueous solution so as to achieve a solid residue content of 13% by mass at 140° C. The resultant polymer corresponds to Formula (3-1). The polymer was found to have a weight average molecular weight Mw of 1,500 as determined by GPC in terms of polystyrene.

### Synthesis Example 3

A 300-ml flask was charged with 19.3 g of tetraethoxysilane, 1.4 g of phenyltrimethoxysilane, 15.5 g of 2,2,5-trimethyl-5-(3-(triethoxysilyl)propyl)-1,3-dioxane-4,6-dione, and 54.4 g of acetone. While the resultant mixture was stirred with a magnetic stirrer, 9.4 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monoethyl ether acetate was added to the aqueous solution so as to achieve solvent proportions of propylene glycol monoethyl ether 80% and propylene glycol monomethyl ether acetate 20% and a solid residue content of 13% by mass at 140° C. The resultant polymer corresponds to Formula (3-2). The polymer was found to have a weight average molecular weight Mw of 1,500 as determined by GPC in terms of polystyrene.

### Synthesis Example 4

A 300-ml flask was charged with 18.2 g of tetraethoxysilane, 1.3 g of phenyltrimethoxysilane, 16.9 g of di-tert-butyl 2-(3-(triethoxysilyl)propyl)malonate, and 54.4 g of acetone. While the resultant mixture was stirred with a magnetic stirrer, 8.8 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monoethyl ether was added to the aqueous solution so as to achieve solvent proportions of propylene glycol monoethyl ether 80% and propylene glycol monomethyl ether acetate 20% and a solid residue content of 13% by mass at 140° C. The resultant polymer corresponds to Formula (3-3). The polymer was found to have a weight average molecular weight Mw of 1,500 as determined by GPC in terms of polystyrene.

### Synthesis Example 5

A 300-ml flask was charged with 20.6 g of tetraethoxysilane, 1.5 g of phenyltrimethoxysilane, 13.9 g of 3-(3-(triethoxysilyl)propyl)dihydrofuran-2,5-dione, and 54.0 g of acetone. While the resultant mixture was stirred with a magnetic stirrer, 10.0 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monoethyl ether was added to the aqueous solution so as to achieve solvent proportions of propylene glycol monoethyl ether 80% and propylene glycol monomethyl ether acetate 20% and a solid residue content of 13% by mass at 140° C. The resultant polymer corresponds to Formula (3-4). The polymer was found to have a weight average molecular weight Mw of 1,500 as determined by GPC in terms of polystyrene.

### Synthesis Example 6

A 300-ml flask was charged with 24.1 g of tetraethoxysilane, 1.6 g of phenyltrimethoxysilane, 4.42 g of triethoxymethylsilane, 5.4 g of 5-(triethoxysilyl)hexahydro-4,7-methanoisobenzofuran-1,3-dione, and 53.4 g of acetone. While the resultant mixture was stirred with a magnetic stirrer, 11.0 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether was added to the aqueous solution so as to achieve a solid residue content of 13% by mass at 140° C. The resultant polymer corresponds to Formula (3-5). The polymer was found to have a weight average molecular weight Mw of 1,500 as determined by GPC in terms of polystyrene.

### Synthesis Example 7

A 300-ml flask was charged with 12.1 g of tetraethoxysilane, 1.3 g of phenyltrimethoxysilane, 23.4 g of 2,2,5-trimethyl-5-(3-(triethoxysilyl)propyl)-1,3-dioxane-4,6-dione, and 55.2 g of acetone. While the resultant mixture was stirred with a magnetic stirrer, 8.0 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 74 g of propylene glycol monomethyl ether was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether was added to the aqueous solution so as to achieve a solid residue content of 13% by mass at 140° C. The resultant polymer corresponds to Formula (3-2). The polymer was found to have a weight average molecular weight Mw of 1,500 as determined by GPC in terms of polystyrene.

### Synthesis Example 8

A 300-ml flask was charged with 19.5 g of tetraethoxysilane, 14.2 g of 5-(triethoxysilyl)hexahydro-4,7-methanoisobenzofuran-1,3-dione, 2.6 g of phenylsulfonylamidepropyltriethoxysilane, and 54.3 g of acetone. While the resultant mixture was stirred with a magnetic stirrer, 9.5 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether was added to the aqueous solution so as to achieve a solid residue content of 13% by mass at 140° C. The resultant polymer corresponds to Formula (3-6). The polymer was found to have a weight average molecular weight Mw of 1,500 as determined by GPC in terms of polystyrene.

### Synthesis Example 9

A 300-ml flask was charged with 17.2 g of tetraethoxysilane, 13.6 g of 5-(triethoxysilyl)hexahydro-4,7-methanoisobenzofuran-1,3-dione, 5.7 g of diallylisocyanatopropyltriethoxysilane, and 54.7 g of acetone. While the resultant mixture was stirred with a magnetic stirrer, 8.9 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 72 g of propylene glycol monomethyl ether was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether was added to the aqueous solution so as to achieve a solid residue content of 13% by mass at 140° C. The resultant polymer corresponds to Formula (3-7). The polymer was found to have a weight average molecular weight Mw of 1,500 as determined by GPC in terms of polystyrene.

### Comparative Synthesis Example 1

A 300-ml flask was charged with 24.1 g of tetraethoxysilane, 1.8 g of phenyltrimethoxysilane, 9.5 g of triethoxymethylsilane, and 53.0 g of acetone. While the resultant mixture was stirred with a magnetic stirrer, 11.7 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether was added to the aqueous solution so as to achieve a solid residue content of 13% by mass at 140° C. The resultant polymer corresponds to the following Formula (4-1). The polymer was found to have a weight average molecular weight Mw of 1,400 as determined by GPC in terms of polystyrene.

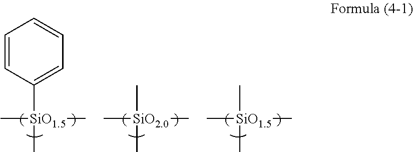

### Preparation of Si-Containing Resist Underlayer Film

Each of the silicon-containing polymers prepared above in Synthesis Examples 1 to 9 and Comparative Synthesis Example 1, an acid, and a solvent were mixed in proportions shown in Table 1, and the resultant mixture was filtered with a fluororesin-made filter (0.1 μm), to thereby prepare a polymer-containing coating liquid. The amount of each polymer shown in Table 1 corresponds not to the amount of the polymer solution, but to the amount of the polymer itself.

In Table 1, MA denotes maleic acid; TPSNO3, triphenylsulfonium nitrate; TPSTFA, triphenylsulfonium trifluoroacetate; TPSML, triphenylsulfonium maleate; BPS, bisphenolsulfone; PGEE, propylene glycol monoethyl ether; and PGMEA, propylene glycol monomethyl ether acetate. The amount of each component is represented by “parts by mass”.

TABLE 1

| | Si polymer | | | | | | |
|---|---|---|---|---|---|---|---|
| | solution | Additive 1 | Additive 2 | | Solvent | | |
| Example 1 | Synthesis | MA | TPSNO3 | | PGEE | PGMEA | Water |
| (parts by mass) | Example 1 | | | | | | |
| | 2 | 0.06 | 0.06 | | 70 | 18 | 12 |
| Example 2 | Synthesis | MA | TPSTFA | | PGME | PGMEA | |
| (parts by mass) | Example 2 | | | | | | |
| | 2 | 0.06 | 0.06 | | 70 | 30 | |
| Example 3 | Synthesis | MA | TPSNO3 | | PGEE | PGMEA | Water |
| (parts by mass) | Example 3 | | | | | | |
| | 2 | 0.06 | 0.06 | | 70 | 18 | 12 |
| Example 4 | Synthesis | MA | TPSTFA | | PGEE | PGMEA | Water |
| (parts by mass) | Example 4 | | | | | | |
| | 2 | 0.06 | 0.06 | | 70 | 18 | 12 |
| Example 5 | Synthesis | MA | TPSML | | PGEE | PGMEA | Water |
| (parts by mass) | Example 5 | | | | | | |
| | 2 | 0.06 | 0.06 | | 70 | 18 | 12 |
| Example 6 | Synthesis | MA | TPSTFA | | PGME | PGMEA | |
| (parts by mass) | Example 6 | | | | | | |
| | 2 | 0.06 | 0.06 | | 70 | 30 | |
| Example 7 | Synthesis | MA | TPSNO3 | | PGME | PGMEA | |
| (parts by mass) | Example 7 | | | | | | |
| | 2 | 0.06 | 0.06 | | 70 | 30 | |
| Example 8 | Synthesis | MA | TPSNO3 | | PGME | PGMEA | |
| (parts by mass) | Example 8 | | | | | | |
| | 2 | 0.06 | 0.06 | | 70 | 30 | |
| Example 9 | Synthesis | MA | TPSTFA | | PGME | PGMEA | |
| (parts by mass) | Example 9 | | | | | | |
| | 2 | 0.06 | 0.06 | | 70 | 30 | |
| Example 10 | Synthesis | MA | TPSNO3 | BPS | PGME | PGMEA | |
| (parts by mass) | Example 8 | | | | | | |
| | 2 | 0.06 | 0.06 | 0.1 | 70 | 30 | |
| Comparative | Comparative | MA | TPSNO3 | | PGME | PGMEA | |
| Example 1 | Synthesis | | | | | | |
| (parts by mass) | Example 1 | | | | | | |
| | 2 | 0.06 | 0.06 | | 70 | 30 | |

### Preparation of Organic Underlayer Film A

In a nitrogen atmosphere, a 100-mL four-necked flask was charged with 6.69 g (0.040 mol) of carbazole (available from Tokyo Chemical Industry Co., Ltd.), 7.28 g (0.040 mol) of 9-fluorenone (available from Tokyo Chemical Industry Co., Ltd.), 0.76 g (0.0040 mol) of p-toluenesulfonic acid monohydrate (available from Tokyo Chemical Industry Co., Ltd.), and 6.69 g of 1,4-dioxane (available from Kanto Chemical Co., Inc.), and the resultant mixture was stirred. The mixture was heated to 100° C. for dissolution, to thereby initiate polymerization. After the elapse of 24 hours, the mixture was left to cool to 60° C. The mixture was then diluted with 34 g of chloroform (available from Kanto Chemical Co., Inc.) and reprecipitated in 168 g of methanol (available from Kanto Chemical Co., Inc.). The resultant precipitate was filtered and dried with a reduced pressure dryer at 80° C. for 24 hours, to thereby yield 9.37 g of an intended polymer (Formula (5-1), hereinafter abbreviated as “PCzFL”).

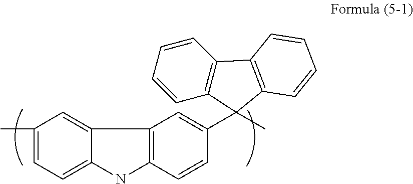

The results of ¹H-NMR analysis of PCzFL were as follows:

¹H-NMR (400 MHZ, DMSO-d₆): δ 7.03-7.55 (br, 12H), δ 7.61-8.10 (br, 4H), δ 11.18 (br, ¹H).

PCzFL was found to have a weight average molecular weight Mw of 2,800 as determined by GPC in terms of polystyrene and a polydispersity Mw/Mn of 1.77.

Subsequently, 20 g of the resultant resin was mixed with 3.0 g of tetramethoxymethyl glycoluril (trade name: Powderlink 1174, available from Mitsui Cytec Ltd.) serving as a crosslinking agent, 0.30 g of pyridinium p-toluenesulfonate serving as a catalyst, and 0.06 g of MEGAFAC R-30 (trade name, available from Dainippon Ink and Chemicals, Inc.) serving as a surfactant, and the mixture was dissolved in 88 g of propylene glycol monomethyl ether acetate, to thereby prepare a solution. Thereafter, the solution was filtered with a polyethylene-made microfilter (pore size: 0.10 μm), and then filtered with a polyethylene-made microfilter (pore size: 0.05 μm), to thereby prepare a solution of a composition for forming an organic underlayer film (layer A) used for a lithography process using a multilayer film.

### Evaluation of Resist Pattern by ArF Exposure: PTD

### Evaluation of Resist Patterning: Evaluation through PTD Process Involving Alkaline Development

The above-prepared organic underlayer film (layer A)-forming composition was applied onto a silicon wafer, and then baked on a hot plate at 240° C. for 60 seconds, to thereby form an organic underlayer film (layer A) having a thickness of 200 nm. Each of the Si-containing resist underlayer film (layer B)-forming compositions prepared in Examples 3, 4, and 6 to 10 and Comparative Example 1 was applied onto layer A, and then baked on a hot plate at 180° C. for 60 seconds, to thereby form an Si-containing resist underlayer film (layer B). The Si-containing resist underlayer film (layer B) was found to have a thickness of 40 nm.

A commercially available resist solution for ArF (trade name: AR2772JN, available from JSR Corporation) was applied onto layer B with a spinner, and then heated on a hot plate at 110° C. for one minute, to thereby form a photoresist film (layer C) having a thickness of 120 nm.

By using a scanner NSR-S307E (available from Nikon Corporation) (wavelength: 193 nm, NA, σ: 0.85, 0.93/0.85), the photoresist film was exposed to light through a mask designed to achieve a line width of 0.062 μm and an interline width of 0.062 μm (i.e., a 0.062 μm line and space (L/S)=1/1 dense line) in the photoresist after development. Thereafter, the photoresist film was baked on a hot plate at 100° C. for 60 seconds and then cooled, followed by development with a 2.38% alkaline aqueous solution for 60 seconds, to thereby form a positive pattern on the resist underlayer film (layer B). The resultant photoresist pattern was evaluated as “Good” if it did not have large pattern peeling, undercut, or a wide-bottomed line (footing).

TABLE 2

| | Pattern shape |
|---|---|
| Example 3 | Good |
| Example 4 | Good |
| Example 6 | Good |
| Example 7 | Good |
| Example 8 | Good |
| Example 9 | Good |
| Example 10 | Good |
| Comparative | Good |
| Example 1 | |

### Evaluation of Resist Pattern by ArF Exposure: NTD

### Evaluation of Resist Patterning: Evaluation through NTD Process Involving Solvent Development

The above-prepared organic underlayer film (layer A)-forming composition was applied onto a silicon wafer, and then baked on a hot plate at 240° C. for 60 seconds, to thereby form an organic underlayer film (layer A) having a thickness of 200 nm. Each of the Si-containing resist underlayer film (layer B)-forming compositions prepared in Examples 1 to 7 and Comparative Example 1 was applied onto layer A, and then baked on a hot plate at 180° C. for 60 seconds, to thereby form an Si-containing resist underlayer film (layer B). The Si-containing resist underlayer film (layer B) was found to have a thickness of 40 nm.

A commercially available photoresist solution (trade name: FAIRS-9521NT05, available from FUJIFILM Corporation) was applied onto layer B with a spinner, and then heated on a hot plate at 100° C. for one minute, to thereby form a photoresist film (layer C) having a thickness of 85 nm.

By using a scanner NSR-S307E (available from Nikon Corporation) (wavelength: 193 nm, NA, σ: 0.85, 0.93/0.85), the photoresist film was exposed to light through a mask designed to achieve a line width of 0.062 μm and an interline width of 0.062 μm (i.e., a 0.062 μm line and space (L/S)=1/1 dense line) in the photoresist after development. Thereafter, the photoresist film was baked on a hot plate at 100° C. for 60 seconds and then cooled, followed by development with a 2.38% alkaline aqueous solution for 60 seconds, to thereby form a positive pattern on the resist underlayer film (layer B). The resultant photoresist pattern was evaluated as “Good” if it did not have large pattern peeling, undercut, or a wide-bottomed line (footing).

TABLE 3

| | Pattern shape |
|---|---|
| Example 1 | Good |
| Example 2 | Good |
| Example 3 | Good |
| Example 4 | Good |
| Example 5 | Good |
| Example 6 | Good |
| Example 7 | Good |
| Comparative | Good |
| Example 1 | |

### Evaluation of Removability with SC-1 Chemical (Aqueous Solution Containing Ammonia and Hydrogen Peroxide)

Each of the Si-containing coating liquids prepared in Examples 1 to 10 and Comparative Example 1 was applied onto a silicon wafer with a spinner. The coating liquid was heated on a hot plate at 180° C. for one minute, to thereby form an Si-containing resist underlayer film. Thereafter, the SC-1 chemical (28% aqueous ammonia/33% aqueous hydrogen peroxide/water=1/1/40) set at 60° C. was applied onto the Si-containing resist underlayer film for three minutes, the SC-1 chemical was rinsed off with water for one minute, and then the resultant film was spin-dried for 30 seconds, followed by observation of a change in the thickness of the Si-containing resist underlayer film between before and after application of the chemical. A film exhibiting a change in thickness of 90% or more was evaluated as “Good,” and a film exhibiting a change in thickness of less than 90% was evaluated as “Not dissolved.”

TABLE 4

| | Removability |
|---|---|
| | with SC-1 |
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Comparative | Not |
| Example 1 | dissolved |

### Evaluation of Removability with SC-1 Chemical after O₂ Etching

Each of the Si-containing coating liquids prepared in Examples 1 to 10 and Comparative Example 1 was applied onto a silicon wafer with a spinner. The coating liquid was heated on a hot plate at 180° C. for one minute, to thereby form an Si-containing resist underlayer film. Subsequently, oxygen etching was performed with a dry etcher (RIE-10NR, available from Samco Inc.) for five seconds. Thereafter, the SC-1 chemical (28% aqueous ammonia/33% aqueous hydrogen peroxide/water=1/1/40) set at 60° C. was applied onto the Si-containing resist underlayer film for three minutes, the SC-1 chemical was rinsed off with water for one minute, and then the resultant film was spin-dried for 30 seconds, followed by observation of a change in the thickness of the Si-containing resist underlayer film between before and after application of the chemical. A film exhibiting a change in thickness of 90% or more was evaluated as “Good,” and a film exhibiting a change in thickness of less than 90% was evaluated as “Not dissolved.”

TABLE 5

| | Removability with |
|---|---|
| | SC-1 after |
| | oxygen etching |
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Comparative | Not |
| Example 1 | dissolved |

### INDUSTRIAL APPLICABILITY

The present invention is useful for formation of a good pattern on an ArF, KrF, or EUV resist underlayer film. In the present invention, mask residues after lithography can be removed only with a chemical without etching, and thus damage to a substrate is reduced. In the present invention, etching is performed through a mask for transfer of a pattern to an underlayer by a lithography process, and the remaining mask after the etching can be removed with a chemical.

1. A method for producing a semiconductor device, the method comprising:
applying a composition for forming a silicon-containing resist underlayer film, wherein the composition comprises a polysiloxane having a unit structure including a carbonyl group-containing functional group, wherein the silicon-containing resist underlayer film is used as a mask layer in a step of removing the mask layer with a hydrogen peroxide-containing chemical after transfer of a pattern to an underlayer by a lithography process onto a semiconductor substrate, followed by baking the composition, to thereby form a resist underlayer film;
applying a resist composition onto the resist underlayer film to thereby form a resist film;
exposing the resist film to light;
developing the resist after the light exposure to thereby form a resist pattern;
etching the resist underlayer film with the resist pattern;
processing the semiconductor substrate with the patterned resist and resist underlayer film; and
removing the mask layer with a hydrogen peroxide-containing chemical.

2. The method for producing a semiconductor device according to claim 1, wherein the unit structure including a carbonyl group-containing functional group includes a cyclic acid anhydride group, a cyclic diester group, or a diester group.

3. The method for producing a semiconductor device according to claim 1, wherein the polysiloxane is a hydrolysis condensate of a hydrolyzable silane containing a silane of the following Formula (1):
R¹ₐR²_{b}Si(R³)_{4-(a+b)} Formula (1)
wherein R¹ is an organic group of the following Formula (1-1), (1-2), (1-3), (1-4), (1-5), or (1-6): 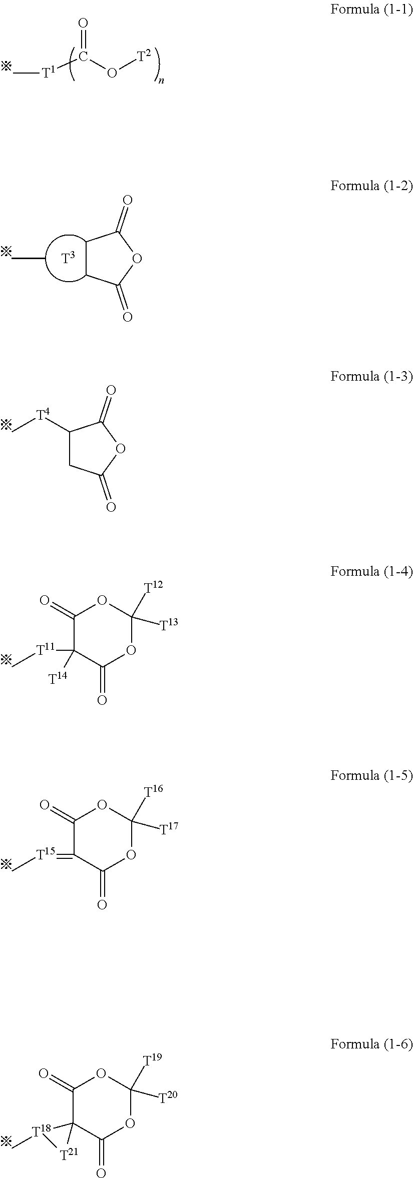
wherein T¹ and T⁴ are each an alkylene group or a cyclic alkylene group; T² is an alkyl group; T³ is a cyclic alkylene group; n is an integer of 1 or 2; T¹¹, T¹⁵, and T¹⁸ are each an alkylene group, a cyclic alkylene group, an alkenylene group, an arylene group, a sulfur atom, an oxygen atom, an oxycarbonyl group, an amide group, a secondary amino group, or any combination of these; T¹², T¹³, T¹⁴, T¹⁶, T¹⁷, T¹⁹, and T²⁰ are each a hydrogen atom or an alkyl group; T²¹ is an alkylene group; and * is a site of bonding to the silicon atom directly or via a linking group and is bonded to the silicon atom via an Si—C bond;
R² is an alkyl group, an aryl group, a halogenated alkyl group, a halogenated aryl group, an alkenyl group, or an organic group having an epoxy group, an acryloyl group, a methacryloyl group, a mercapto group, an amino group, or a cyano group, and is bonded to the silicon atom via an Si—C bond;
R³ is an alkoxy group, an acyloxy group, or a halogen atom; and
a is an integer of 1, b is an integer of 0 or 1, and a+b is an integer of 1 or 2.

4. The method for producing a semiconductor device according to claim 1, wherein the polysiloxane further has a unit structure including an amide group-containing organic group.

5. The method for producing a semiconductor device according to claim 4, wherein the amide group is a sulfonamide group or a diallyl isocyanurate group.

6. The method for producing a semiconductor device according to claim 3, wherein the polysiloxane is a cohydrolysis condensate of a hydrolyzable silane containing a silane of Formula (1) and a silane of the following Formula (2):
R⁴ₐR⁵_{b}Si(R⁶)_{4-(a+b)} Formula (2)
wherein R⁴ is an organic group of the following Formula (2-1) or (2-2): 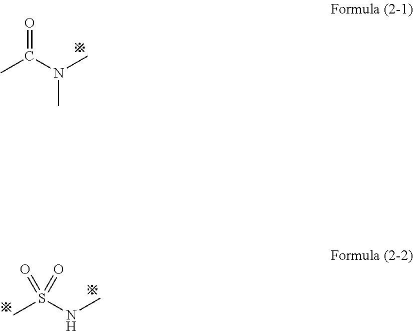
and is bonded to the silicon atom via an Si—C bond;
R⁵ is an alkyl group, an aryl group, a halogenated alkyl group, a halogenated aryl group, an alkenyl group, or an organic group having an epoxy group, an acryloyl group, a methacryloyl group, a mercapto group, an amino group, or a cyano group, and is bonded to the silicon atom via an Si—C bond;
R⁶ is an alkoxy group, an acyloxy group, or a halogen atom;
a is an integer of 1, b is an integer of 0 or 1, and a+b is an integer of 1 or 2; and
* is a site of bonding to the silicon atom directly or via a linking group.

7. The method for producing a semiconductor device according to claim 6, wherein the polysiloxane is a cohydrolysis condensate of a hydrolyzable silane containing a silane of Formula (1), a silane of Formula (2), and an additional silane, and the additional silane is at least one silane selected from the group consisting of
a silane of the following Formula (3):
R⁷ₐSi(R⁸)₄₋ₐ Formula (3)
wherein R⁷ is an alkyl group, an aryl group, a halogenated alkyl group, a halogenated aryl group, an alkenyl group, or an organic group having an epoxy group, an acryloyl group, a methacryloyl group, a mercapto group, or a cyano group, and is bonded to the silicon atom via an Si—C bond; R⁸ is an alkoxy group, an acyloxy group, or a halogen atom; and a is an integer of 0 to 3, and
a silane of the following Formula (4):
[R⁹_{c}Si(R¹⁰)_{3-c}]₂Y_{b} Formula (4)
wherein R⁹ is an alkyl group and is bonded to the silicon atom via an Si—C bond; R¹⁰ is an alkoxy group, an acyloxy group, or a halogen group; Y is an alkylene group or an arylene group; b is an integer of 0 or 1; and c is an integer of 0 or 1.

8. The method for producing a semiconductor device according to claim 1, wherein the composition for forming a silicon-containing resist underlayer film further comprises a photoacid generator.

9. The method for producing a semiconductor device according to claim 1, wherein the composition for forming a silicon-containing resist underlayer film further comprises a metal oxide.

10. The method for producing a semiconductor device according to claim 1, wherein the hydrogen peroxide-containing chemical is an aqueous solution containing ammonia and hydrogen peroxide, an aqueous solution containing hydrochloric acid and hydrogen peroxide, an aqueous solution containing sulfuric acid and hydrogen peroxide, or an aqueous solution containing hydrofluoric acid and hydrogen peroxide.

11. A method for producing a semiconductor device, the method comprising:
forming an organic underlayer film on a semiconductor substrate;
applying a composition for forming a silicon-containing resist underlayer film, wherein the composition comprises a polysiloxane having a unit structure including a carbonyl group-containing functional group, wherein the silicon-containing resist underlayer film is used as a mask layer in a step of removing the mask layer with a hydrogen peroxide-containing chemical after transfer of a pattern to an underlayer by a lithography process onto the organic underlayer film, followed by baking the composition, to thereby form a resist underlayer film;
applying a resist composition onto the resist underlayer film to thereby form a resist film;
exposing the resist film to light;
developing the resist after the light exposure to thereby form a resist pattern;
etching the resist underlayer film with the resist pattern;
etching the organic underlayer film with the patterned resist underlayer film;
processing the semiconductor substrate with the patterned organic underlayer film; and
removing the mask layer with a hydrogen peroxide-containing chemical.

12. The method for producing a semiconductor device according to claim 11, wherein the substrate is processed by etching or ion implantation.
